(19) United States
(12) Patent Application Publication
(10) Pub. No.: US 2025/0255109 A1
(43) Pub. Date: Aug. 7, 2025

(54) DISPLAY PANEL AND MANUFACTURING METHOD FOR THE SAME

(71) Applicant: Samsung Display Co., Ltd., Yongin-si (KR)

(72) Inventors: YOOLGUK KIM, Yongin-si (KR); JIYOON KIM, Yongin-si (KR); HYEONSIK KIM, Yongin-si (KR); SANGHO LEE, Yongin-si (KR); HEEWOON IM, Yongin-si (KR)

(73) Assignee: Samsung Display Co., Ltd., Yongin-si (KR)

(21) Appl. No.: 18/953,602

(22) Filed: Nov. 20, 2024

(30) Foreign Application Priority Data
Feb. 6, 2024 (KR) 10-2024-0018268

(51) Int. Cl. H10K 59/122; H10K 59/12; H10K 59/131; H10K 59/35

(52) U.S. Cl. CPC H10K 59/122; H10K 59/1201; H10K 59/131; H10K 59/353

(57) ABSTRACT

Disclosed is a display panel including a first light emitting element including a first anode, a first cathode, and a first intermediate layer disposed between the first anode and the first cathode, a second light emitting element including a second cathode, a second anode, and a second intermediate layer disposed between the second cathode and the second anode, a first transistor, a second transistor, a connection wiring line, and a pixel defining film, and the second cathode includes an end portion connected to a light emitting connection part and another end portion spaced apart from the end portion on a cross section.

### CROSS-REFERENCE TO RELATED APPLICATION(S)

This application claims priority to and benefits of Korean Patent Application No. 10-2024-0018268 under 35 U.S.C. § 119, filed on Feb. 6, 2024, in the Korean Intellectual Property Office, the entire contents of which are incorporated herein by reference.

### BACKGROUND

Embodiments described herein relate to a device and a method, and more particularly, relate to a display panel having improved display quality and a method of manufacturing the display panel.

Multimedia electronic devices such as a television (TV), a mobile phone, a tablet personal computer (PC), a computer, a navigation system, a game console, etc. include display panels for displaying images.

The display panel includes a light emitting element and a circuit for driving the light emitting element. The light emitting elements included in the display panel emit lights and generate images according to a voltage applied from the circuit. Research on connection between the light emitting element and the circuit has been conducted to improve the reliability of the display panel.

### SUMMARY

Embodiments provide a display panel capable of preventing damage to a light emitting layer and a method of manufacturing the display panel.

Embodiments provide a display panel capable of preventing reliability of display quality from being degraded and a method of manufacturing the display panel.

However, embodiments are not limited to those set forth herein. The above and other embodiments will become more apparent to one of ordinary skill in the art to which the disclosure pertains by referencing the detailed description of the disclosure given below.

According to an embodiment, a display panel includes a first light emitting element including a first anode, a first cathode disposed on the first anode, and a first intermediate layer disposed between the first anode and the first cathode, a second light emitting element including a second cathode, a second anode disposed on the second cathode, and a second intermediate layer disposed between the second cathode and the second anode, a first transistor electrically connected to the first light emitting element, a second transistor electrically connected to the second light emitting element, a connection wiring line disposed between the second light emitting element and the second transistor on a cross section and including a driving connection part connected to the second transistor and a light emitting connection part connected to the second anode, and a pixel defining film including a first light emitting opening overlapping the first light emitting element and in which a portion of the first cathode is disposed, a second light emitting opening overlapping the second light emitting element and spaced apart from the first light emitting opening, the second light emitting opening in which a portion of the second anode is disposed, and a first connection opening spaced apart from the first light emitting opening and the second light emitting opening, wherein the second anode includes an end portion connected to the light emitting connection part and another end portion spaced apart from the end portion on a cross section.

The display panel may further include a hydrogen supply film disposed under the second cathode and overlapping the second light emitting opening.

The display panel may further include a separator disposed on the pixel defining film and disconnecting the second anode.

The first intermediate layer may include a light emitting material that generates a light having a blue color, and the second intermediate layer may include a light emitting material that generates a light having a color different from the blue color.

The first intermediate layer may include a first hole control layer disposed on the pixel defining film, a first light emitting layer that is disposed on the first hole control layer and generates a light having a first color, and a first electron control layer disposed on the first light emitting layer, and the second intermediate layer may include a second electron control layer disposed on the pixel defining film, a second light emitting layer disposed on the second electron control layer and including a light emitting material that generates a light having a color different form the first color, and a second hole control layer disposed on the second light emitting layer.

The hydrogen supply film may contain silicon nitride (SiNₓ) or poly acrylic acid.

A thickness of the second electron control layer may be about 200 Å or more and about 400 Å or less.

The connection wiring line may include a first layer containing titanium (Ti), a second layer disposed on the first layer and containing aluminum (Al), and a third layer disposed on the second layer and containing titanium (Ti).

The first cathode and the second cathode may be spaced apart from each other in plan view.

The first light emitting element may be disposed in a first area, the second light emitting element may be disposed in a second area, the first area and the second area may be divided by the separator, the first connection opening may be spaced apart from the first area in plan view.

According to an embodiment, a display panel includes a first light emitting element including a first anode, a first cathode disposed on the first anode, and a first intermediate layer disposed between the first anode and the first cathode, a second light emitting element including a second cathode, a second anode disposed on the second cathode, and a second intermediate layer disposed between the second cathode and the second anode, a third light emitting element including a third cathode, a third anode disposed on the third cathode, and a third intermediate layer disposed between the third cathode and the third anode, a first transistor electrically connected to the first light emitting element, a second transistor electrically connected to the second light emitting element, a third transistor electrically connected to the third light emitting element, a first connection wiring line disposed between the second light emitting element and the second transistor on a cross section and including a first driving connection part connected to the second transistor and a first light emitting connection part connected to the second anode, and a second connection wiring line disposed between the third light emitting element and the third transistor on a cross section and including a second driving connection part connected to the third transistor and a second light emitting connection part connected to the third anode, wherein the second anode includes an end portion connected to the first light emitting connection part and another end portion spaced apart from the end portion on a cross section, and the third anode includes an end portion connected to the second light emitting connection part and another end portion spaced apart from the end portion on a cross section.

The first intermediate layer may include a light emitting material that generates a light having a blue color, the second intermediate layer may include a light emitting material that generates a light having a red color, and the third intermediate layer may include a light emitting material that generates a light having a green color.

The display panel may further include a first hydrogen supply film disposed under the second cathode, and a second hydrogen supply film disposed under the third cathode.

The display panel may further include a separator disconnecting the second anode and the third anode.

The second cathode and the third cathode may be electrically connected to each other.

Each of the first connection wiring line and the second connection wiring line may include a first layer containing titanium (Ti), a second layer disposed on the first layer and containing aluminum (Al), and a third layer disposed on the second layer and containing titanium (Ti).

The first light emitting element may be disposed in a first area, the second light emitting element may be disposed in a second area, the third light emitting element may be disposed in a third area, the first area and the second area may be divided by the separator, the first light emitting connection part and the second light emitting connection part may be spaced apart from the first area in plan view.

According to an embodiment, a method of manufacturing a display panel includes forming a first lower electrode and a second lower electrode on a base layer, forming a first light emitting opening through which at least a portion of the first lower electrode is exposed and a second light emitting opening through which at least a portion of the second lower electrode is exposed, the first light emitting opening and the second light emitting opening being arranged on the base layer and covering the first lower electrode and the second lower electrode, forming a first hole control layer, a first light emitting layer, and a first electron control layer inside the first light emitting opening, and forming a second electron control layer, a second light emitting layer, and a second hole control layer inside the second light emitting opening, wherein the first hole control layer and the second hole control layer are formed simultaneously.

The first and second hole control layers, the first and second light emitting layers, and the first and second electron control layers may be formed by an inkjet manner.

The method may further include pattering the base layer and forming a hydrogen supply film on the patterned base layer before the first lower electrode and the second lower electrode are formed on the base layer, wherein the second lower electrode may be formed on the hydrogen supply film.

### BRIEF DESCRIPTION OF THE DRAWINGS

The above and other objects and features of the disclosure will become apparent by describing in detail embodiments thereof with reference to the accompanying drawings.

FIG. 1 is a schematic block diagram of a display device according to an embodiment.

FIG. 2 is a schematic diagram of an equivalent circuit of a pixel according to an embodiment.

FIGS. 3A and 3B are schematic plan views of a display panel according to an embodiment.

FIGS. 4A, 4B, and 4C are enlarged schematic plan views illustrating a portion of the display panel according to an embodiment.

FIG. 5 is a schematic cross-sectional view of the display panel according to an embodiment.

FIGS. 6A, 6B, and 6C are enlarged schematic cross-sectional views of the portion of the display panel according to an embodiment.

FIG. 7 is an enlarged schematic cross-sectional view of the portion of the display panel according to an embodiment.

FIGS. 8A and 8B are schematic cross-sectional views illustrating light emitting elements according to an embodiment.

FIG. 9 is an enlarged schematic cross-sectional view of the portion of the display panel according to an embodiment.

FIGS. 10A, 10B, 10C, 10D, 10E, and 10F are schematic cross-sectional views illustrating a method of manufacturing the display panel according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical terms and scientific terms) used in the description have the same meaning as commonly understood by those skilled in the art to which the disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, an embodiment will be described with reference to the accompanying drawings.

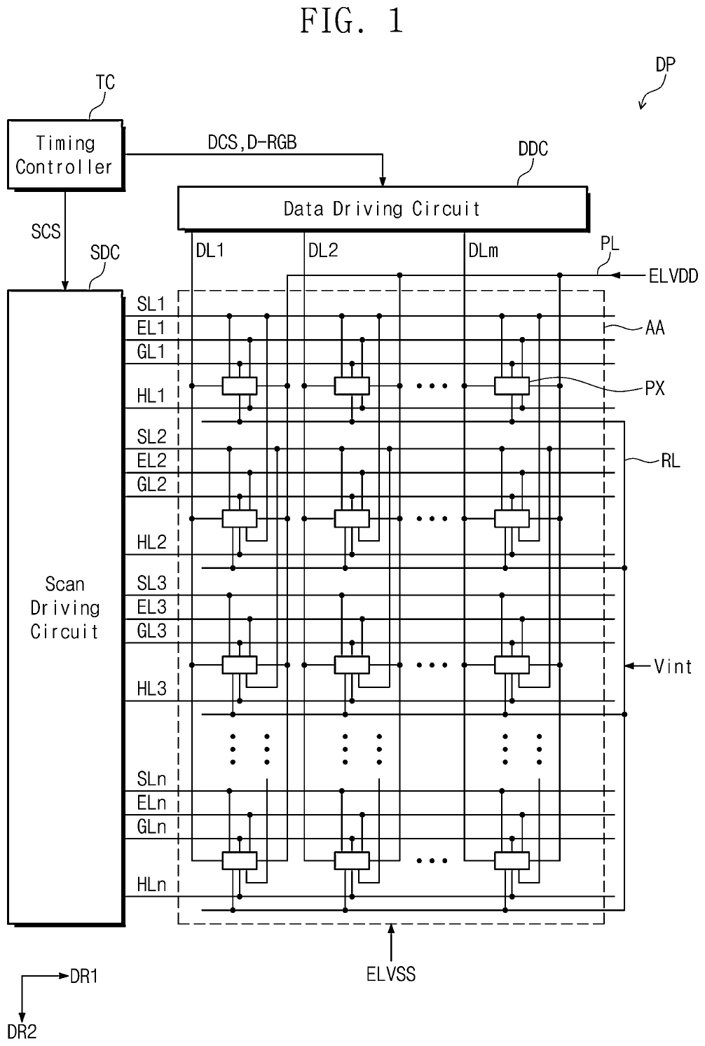

FIG. 1 is a schematic block diagram of a display device according to an embodiment.

Referring to FIG. 1, a display panel DP may include a timing controller TC, a scan driving unit SDC, a data driving unit DDC, and pixels PX overlapping an active area AA. In an embodiment, the display panel DP is described as a light emitting display panel. The light emitting display panel may include an organic light emitting display panel, an inorganic light emitting display panel, and a quantum dot light emitting display panel. In an embodiment, the organic light emitting display panel will be described in detail as an example.

The timing controller TC may receive input image signals, may convert data formats of the input image signals to meet interface specifications with the scan driving unit SDC, and may generate image data D-RGB. The timing controller TC may output the image data D-RGB and various control signals DCS and SCS.

The scan driving unit SDC may receive the scan control signal SCS from the timing controller TC. The scan control signal SCS may include a vertical start signal that starts an operation of the scan driving unit SDC, a clock signal for determining output timings of the signals, and the like. The scan driving unit SDC may generate scan signals and sequentially may output the scan signals to corresponding signal lines SL1 to SLn and GL1 to GLn. Further, the scan driving unit SDC may generate light emitting control signals in response to the scan control signal SCS and may output the light emitting control signals to corresponding signal lines EL1 to ELn.

FIG. 1 illustrates that the scan signals and the light emitting control signals are output from the single scan driving unit SDC, but embodiments are not limited thereto. In an embodiment, scan driving units may divide, generate, and then output the scan signals and may divide, generate, and then output the light emitting control signals. Further, in an embodiment, a driving circuit that generates and outputs the scan signals and a driving circuit that generates and outputs the light emitting control signals may be distinguished from each other.

The data driving unit DDC may receive the data control signal DCS and the image data D-RGB from the timing controller TC. The data driving unit DDC may convert the image data D-RGB into data signals and may output the data signals to data lines DL1 to DLm, which will be described below. The data signals may be analog voltages corresponding to grayscale values of the image data D-RGB.

The display panel DP may include a first group of the scan lines SL1 to SLn, a second group of the scan lines GL1 to GLn, a third group of scan lines HL1 to HLn, the light emitting lines EL1 to ELn, the data lines DL1 to DLm, a first voltage line PL, a second voltage line RL, and the pixels PX. The first group of the scan lines SL1 to SLn, the second group of the scan lines GL1 to GLn, the third group of the scan lines HL1 to HLn, and the light emitting lines EL1 to ELn extend in a first direction DR1 and may be arranged in a second direction DR2 intersecting the first direction DR1.

The data lines DL1 to DLm may be insulated from and intersect the first group of the scan lines SL1 to SLn, the second group of the scan lines GL1 to GLn, the third group of the scan lines HL1 to HLn, and the light emitting lines EL1 to ELn. Each of the pixels PX may be connected to a corresponding signal line among the signal lines. A connection relationship between the pixels PX and the signal lines may change according to a configuration of a driving circuit of the pixels PX.

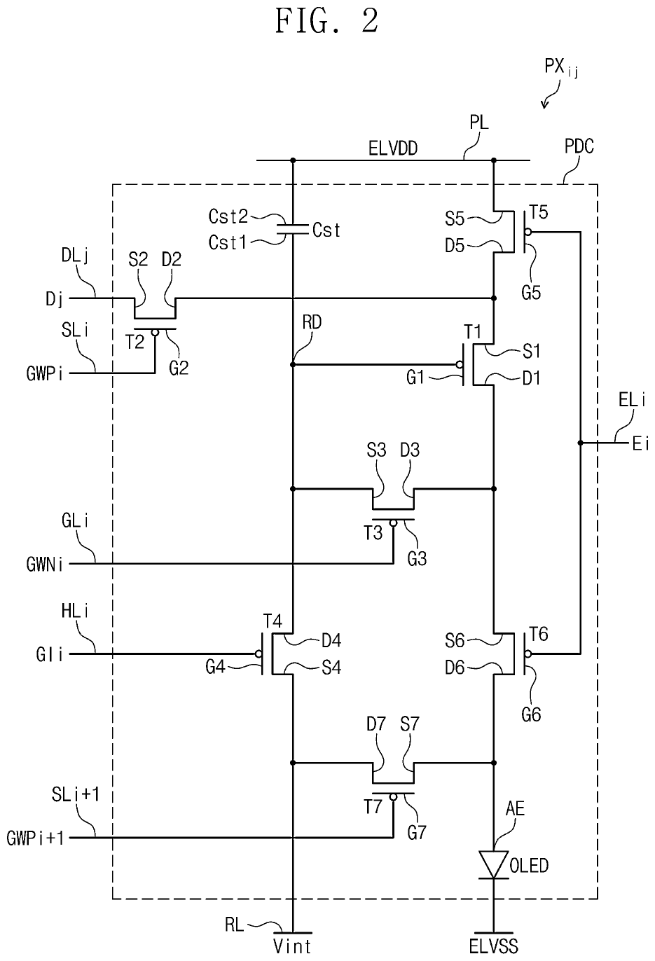

The first voltage line PL may receive a first power voltage ELVDD. The second voltage line RL may receive an initialization voltage Vint. The initialization voltage Vint may have a level lower than the first power voltage ELVDD. A second power voltage ELVSS may be applied to a light emitting element OLED (see FIG. 2). The second power voltage ELVSS may have a lower level than the first power voltage ELVDD.

According to the disclosure, “conductive patterns” described in the appended claims may correspond to at least one of the scan lines, the data lines, and power lines.

The pixels PX may include a groups that generate lights having different colors. For example, the pixels PX may include red pixels that generate red lights, green pixels that generate green lights, and blue pixels that generate blue lights. A light emitting element of the red pixel, a light emitting element of the green pixel, and a light emitting element of the blue pixel may include light emitting layers made of different materials.

A pixel driving unit PDC (see FIG. 2) included in each of the pixels PX may include transistors, a capacitor connected (e.g., electrically connected) to the transistors, and the above-described conductive patterns. At least one of the scan driving unit SDC and the data driving unit DDC may include transistors formed by the same process as the pixel driving unit PDC (see FIG. 2).

The signal lines, the pixels PX, the scan driving unit SDC, and the data driving unit DDC, which are described above, may be formed on a base layer through photolithography processes. Insulating layers may be formed on the base layer through a plurality of times of deposition processes or coating processes. The insulating layers may be thin films arranged to correspond to the pixels PX, and some of the insulating layers may include an insulating pattern that overlaps only a specific conductive pattern. The insulating layers include an organic layer and/or an inorganic layer.

FIG. 2 is a schematic diagram of an equivalent circuit of a pixel according to an embodiment.

FIG. 2 illustratively illustrates a pixel PXij connected to an i^{th} scan line SLi (for supplying an i^{th} scan signal GWPi) among the first group of the scan lines SL1 to SLn and connected to a j^{th} data line DLj (for supplying a j^{th} data signal Dj) among the data lines DL1 to DLm.

In an embodiment, the pixel driving unit PDC may include first to seventh transistors T1 to T7, a capacitor Cst, and the above-described conductive patterns. In an embodiment, it is described that the first transistor T1, the second transistor T2, and the fifth transistor T5 to the seventh transistor T7 are P-type transistors and the third transistor T3 and the fourth transistor T4 are N-type transistors. However, embodiments are not limited thereto, and the first to seventh transistors T1 to T7 may be implemented as either a P-type transistor or an N-type transistor. Further, in another example, at least one of the first to seventh transistors T1 to T7 may be omitted.

In an embodiment, the first transistor T1 may be a driving transistor, and the second transistor T2 may be a switching transistor. The capacitor Cst may be connected between the first voltage line PL that receives the first power voltage ELVDD and a reference node RD. The capacitor Cst may include a first electrode Cst1 connected to the reference node RD and a second electrode Cst2 connected to the first voltage line PL.

The first transistor T1 may be connected between the first voltage line PL and one electrode of the light emitting element OLED. A source S1 of the first transistor T1 may be connected (e.g., electrically connected) to the first voltage line PL. Another transistor may be disposed between the source S1 of the first transistor T1 and the first voltage line PL or may be omitted.

A drain D1 of the first transistor T1 may be connected (e.g., electrically connected) to a first electrode AE of the light emitting element OLED. Another transistor may be disposed between the drain D1 of the first transistor T1 and the first electrode AE of the light emitting element OLED or may be omitted. A gate G1 of the first transistor T1 may be connected (e.g., electrically connected) to the reference node RD.

The second transistor T2 may be connected between the j^{th} data line DLj and the source S1 of the first transistor T1. A source S2 of the second transistor T2 may be connected (e.g., electrically connected) to the j^{th} data line DLj, and a drain D2 of the second transistor T2 may be connected (e.g., electrically connected) to the source S1 of the first transistor T1. In an embodiment, a gate G2 of the second transistor T2 may be connected (e.g., electrically connected) to the i^{th} scan line SLi of the first group.

The third transistor T3 may be connected between the reference node RD and the drain D1 of the first transistor T1. A drain D3 of the third transistor T3 may be connected (e.g., electrically connected) to the drain D1 of the first transistor T1, and a source S3 of the third transistor T3 may be connected (e.g., electrically connected) to the reference node RD. In an embodiment, a gate G3 of the third transistor T3 may be connected (e.g., electrically connected) to the i^{th} scan line GLi of the second group (for supplying an i^{th} scan signal GWNi).

The fourth transistor T4 may be connected between the reference node RD and the second voltage line RL. A drain D4 of the fourth transistor T4 may be connected (e.g., electrically connected) to the reference node RD, and a source S4 of the fourth transistor T4 may be connected (e.g., electrically connected) to the second voltage line RL. In an embodiment, a gate G4 of the fourth transistor T4 may be connected (e.g., electrically connected) to the i^{th} scan line HLi of the third group for supplying an i^{th} scan signal GIi.

The fifth transistor T5 may be connected between the first voltage line PL and the source S1 of the first transistor T1. A source S5 of the fifth transistor T5 may be connected (e.g., electrically connected) to the first voltage line PL, and a drain D5 of the fifth transistor T5 may be connected (e.g., electrically connected) to the source S1 of the first transistor T1. A gate G5 of the fifth transistor T5 may be connected (e.g., electrically connected) to the i^{th} light emitting line ELi for supplying an i^{th} light emitting signal Ei.

The sixth transistor T6 may be connected between the drain D1 of the first transistor T1 and the light emitting element OLED. A source S6 of the sixth transistor T6 may be connected (e.g., electrically connected) to the drain D1 of the first transistor T1, and a drain D6 of the sixth transistor T6 may be connected (e.g., electrically connected) to the first electrode AE of the light emitting element OLED. A gate G6 of the sixth transistor T6 may be connected (e.g., electrically connected) to the i^{th} light emitting line ELi.

The seventh transistor T7 may be connected between the drain D6 of the sixth transistor T6 and the second voltage line RL. A source S7 of the seventh transistor T7 may be connected (e.g., electrically connected) to the drain D6 of the sixth transistor T6, and a drain D7 of the seventh transistor T7 may be connected (e.g., electrically connected) to the second voltage line RL. A gate G7 of the seventh transistor T7 may be connected (e.g., electrically connected) to the (i+1)^{th} scan line SLi+1 of the first group for supplying an (i+1)^{th} scan signal GWPi+1.

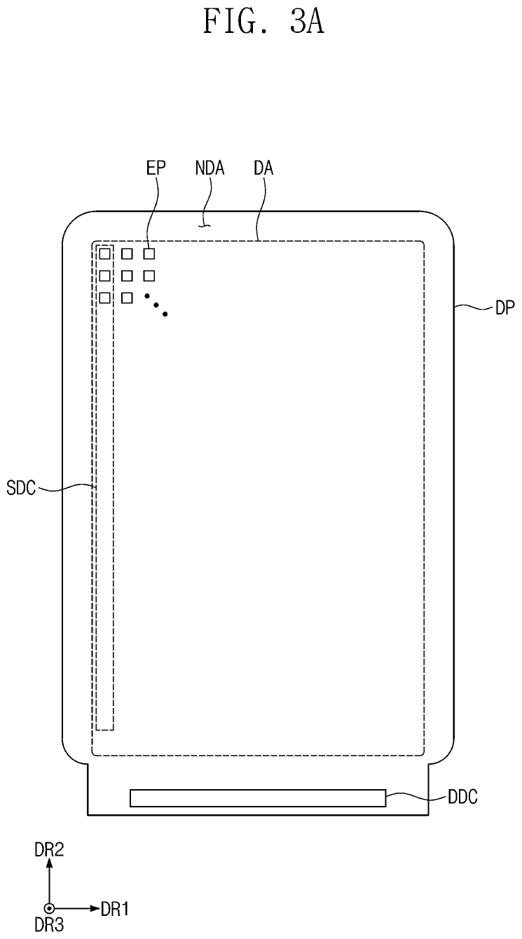

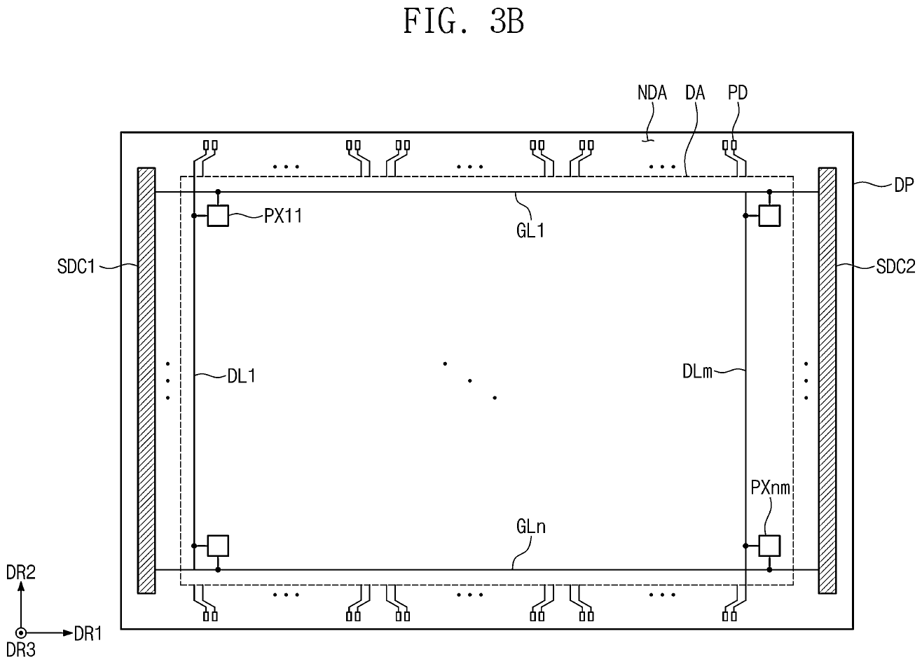

FIGS. 3A and 3B are schematic plan views of a display panel DP according to an embodiment.

FIGS. 3A and 3B are schematic plan views illustrating a display panel DP according to an embodiment. In FIGS. 3A and 3B, some components are omitted. Hereinafter, the disclosure will be described with reference to FIGS. 3A and 3B.

Referring to FIG. 3A, the display panel DP according to an embodiment may be divided into a display area DA and a peripheral area NDA (or a non-display area). The display area DA may include light emitting units EP.

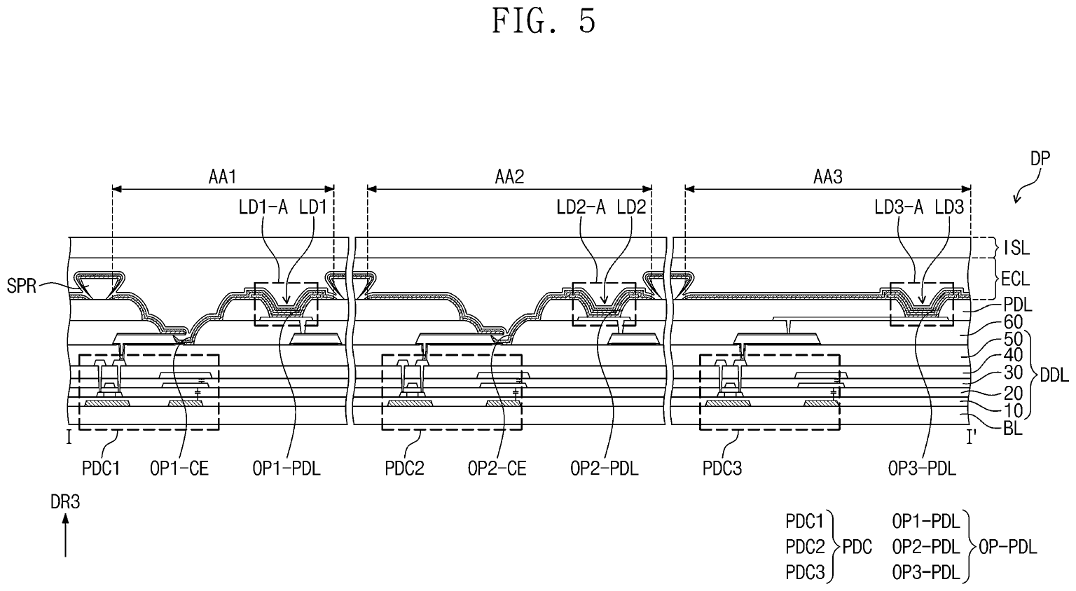

The light emitting units EP may be areas emitting lights by the pixels PXij (see FIG. 2). For example, each of the light emitting units EP may correspond to a light emitting opening OP-PDL (see FIG. 5), which will be described below. The light emitting opening OP-PDL may be referred to as an opening or an opening portion.

The peripheral area NDA may be disposed adjacent to the display area DA. In an embodiment, it is illustrated that the peripheral area NDA has a shape surrounding an edge of the display area DA. However, this is illustratively illustrated, but the peripheral area NDA may be disposed on a side of the display area DA or may be omitted, and embodiments are not limited thereto.

In an embodiment, the scan driving unit SDC may be disposed in the display area DA, and the data driving unit DDC may be disposed in the peripheral area NDA. The scan driving unit SDC may overlap at least some of the light emitting units EP arranged in the display area DA in plan view. As the scan driving unit SDC is disposed in the display area DA, an area of the peripheral area NDA may be reduced as compared to a display panel according to the related art in which a scan driving unit is disposed in a peripheral area, and the display device having a thin bezel may be readily implemented.

For example, unlike the illustration of FIG. 3A, the scan driving unit SDC may be provided as two distinct parts. The two scan driving units SDC may be spaced apart from each other in a left-right direction with a center of the display area DA interposed therebetween. In another example, the scan driving units SDC may be provided as two or more scan driving units SDC, and embodiments are not limited thereto.

FIG. 3A illustrates an example of the display panel DP, and the data driving unit DDC may be disposed in the display area DA. For example, some of the light emitting units EP arranged in the display area DA may overlap the data driving unit DDC in plan view.

In an embodiment, the data driving unit DDC may be provided (or formed) in the form of a separate driving chip, which is independent of the display panel DP and connected to the display panel DP. However, this is illustratively described, and the data driving unit DDC and the scan driving unit SDC may be formed in the same process to form the display panel DP, but embodiments are not limited thereto.

As illustrated in FIG. 3B, a length of the display panel DP in the first direction DR1 may be greater than a length of the display panel DP in the second direction DR2. It is illustratively illustrated that pixels PX11 to PXnm arranged in n rows and m columns are arranged in the display area DA. In an embodiment, the display panel DP may include scan driving units SDC1 and SDC2. It is illustratively illustrated that the scan driving units SDC1 and SDC2 include the first scan driving unit SDC1 and the second scan driving unit SDC2 that are spaced apart from each other in the first direction DR1.

The first scan driving unit SDC1 may be connected to some of the scan lines GL1 to GLn, and the second scan driving unit SDC2 may be connected to the others of the scan lines GL1 to GLn. For example, the first scan driving unit SDC1 may be connected to odd-numbered scan lines among the scan lines GL1 to GLn, and the second scan driving unit SDC2 may be connected to even-numbered scan lines among the scan lines GL1 to GLn.

For descriptive convenience, FIG. 3B illustrates pads PD of the data lines DL1 to DLm. The pads PD may be defined at end portions of the data lines DL1 to DLm. The data lines DL1 to DLm may be connected to the data driving unit DDC (see FIG. 3A) through the pads PD.

According to an embodiment, the pads PD may be dividedly arranged at positions of the peripheral area NDA spaced apart from each other with the display area DA interposed therebetween. For example, some of the pads PD may be arranged on an upper side, e.g., on a side adjacent to the first scan line GL1 among the scan lines GL1 to GLn, and the others of the pads PD may be arranged on a lower side, e.g., on a side adjacent to the last scan line GLn among the scan lines GL1 to GLn. In an embodiment, the pads PD connected to odd-numbered data lines among the data lines DL1 to DLm may be arranged on an upper side, and the pads PD connected to even-numbered data lines among the data lines DL1 to DLm may be arranged on a lower side.

For example, the display panel DP may include upper data driving units connected to the pads PD arranged on the upper side and/or lower data driving units connected to the pads PD arranged on the lower side. However, this is illustratively described, and the display panel DP may also include an upper data driving unit connected to the pads PD arranged on the upper side and/or a lower data driving unit connected to the pads PD arranged on the lower side. The pads PD according to an embodiment may be disposed on only one side of the display panel DP and connected to a single data driving unit, but embodiments are not limited thereto.

Further, as illustrated in FIG. 3A, in the display panel DP in FIG. 3B, the scan driving unit SDC and/or the data driving unit DDC may be arranged in the display area DA. Accordingly, some of the light emitting units EP arranged in the display area DA may overlap the scan driving unit SDC and/or the data driving unit DDC in plan view.

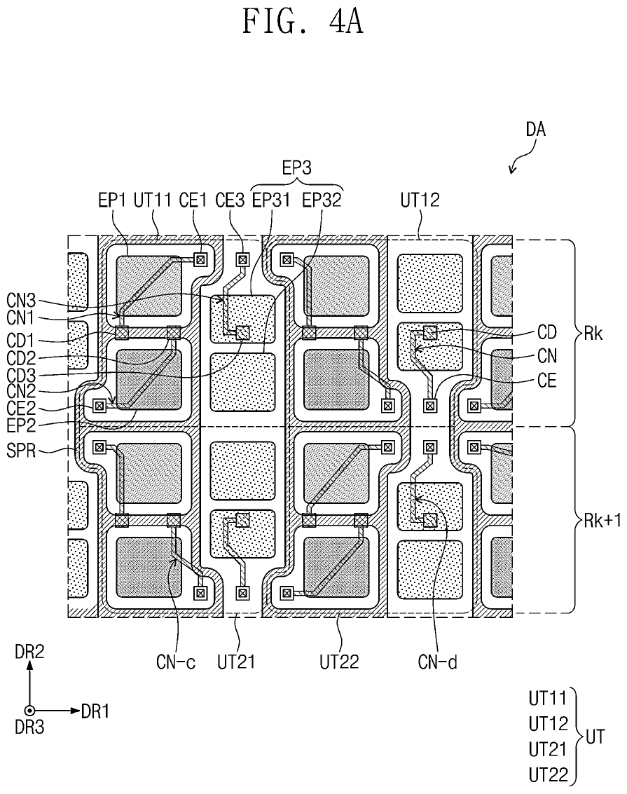

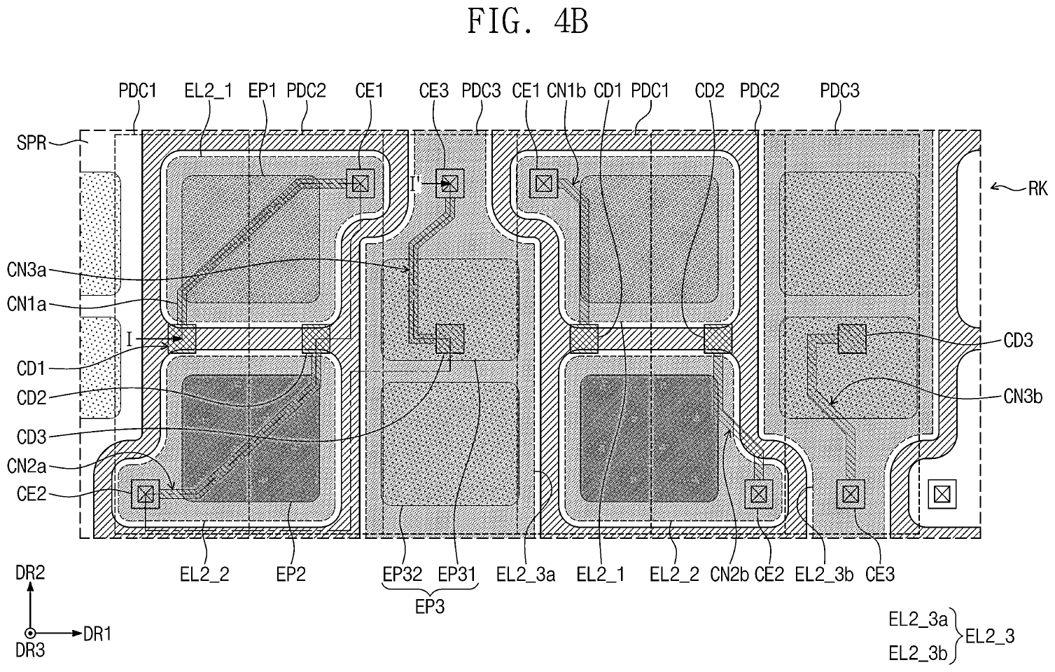

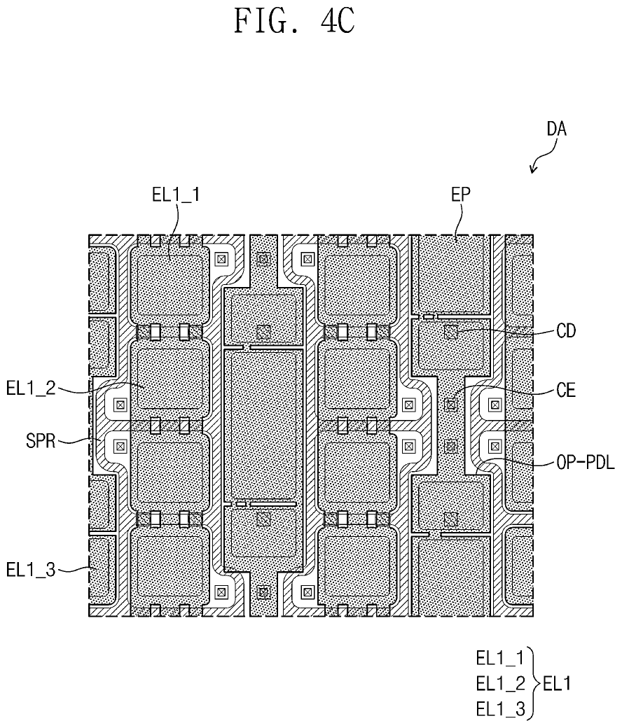

FIGS. 4A to 4C are enlarged schematic plan views illustrating a portion of the display panel DP according to an embodiment.

FIG. 4A illustrates an area in which four light emitting units are arranged in two rows and two columns, and FIG. 4B is an enlarged schematic view illustrating a partial area illustrated in FIG. 4A. In FIG. 4C, some components illustrated in FIG. 4A are omitted or emphasized. Hereinafter, the disclosure will be described with reference to FIGS. 4A to 4C.

FIG. 4A illustrates light emitting units UT11, UT12, UT21, and UT22 in two rows and two columns. The light emitting units in a first row Rk may include light emitting units forming the first row first column light emitting unit UT11 and the first row second column light emitting unit UT12, and the light emitting units in a second row Rk+1 may include light emitting units forming the second row first column light emitting unit UT21 and the second row second column light emitting unit UT22. FIG. 4B illustrates the light emitting units in the first row Rk. FIGS. 4A to 4C illustrate a separator SPR, light emitting units EP1, EP2, and EP3 arranged in an area partitioned by the separator SPR, connection wiring lines CN1, CN2, and CN3, a first electrode EL1, and second electrodes EL2_1, EL2_2, and EL2_3 among components of the display panel DP.

As described above, each of the light emitting units EP1, EP2, and EP3 may correspond to the light emitting opening OP-PDL, which will be described below. For example, the light emitting units EP1, EP2, and EP3 may be areas in which lights are emitted by the above-described light emitting elements and may correspond to a unit forming an image displayed on the display panel DP (see FIG. 1). In more detail, the light emitting units EP1, EP2, and EP3 may correspond to an area defined by the light emitting opening OP-PDL (see FIG. 5), which will be described below, e.g., an area defined by a lower side of the light emitting opening OP-PDL.

The light emitting units EP1, EP2, and EP3 may include the first light emitting unit EP1, the second light emitting unit EP2, and the third light emitting unit EP3. The first light emitting unit EP1, the second light emitting unit EP2, and the third light emitting unit EP3 may emit lights having different colors from each other. For example, the first light emitting unit EP1 may emit a red light, the second light emitting unit EP2 may emit a green light, and the third light emitting unit EP3 may emit a blue light. However, a combination of the colors is not limited thereto. Further, at least two of the light emitting units EP1, EP2, and EP3 may emit lights having the same color. For example, all the first to third light emitting units EP1, EP2, and EP3 may emit blue lights or may emit white lights.

For example, among the light emitting units EP1, EP2, and EP3, the third light emitting unit EP3 that displays a light emitted by a third light emitting element may include two sub-light emitting units EP31 and EP32 spaced apart from each other in the second direction DR2. However, this is illustratively illustrated, and the third light emitting unit EP3 may be provided as one pattern having an integral shape like the other light emitting units EP1 and EP2, and at least one of the other light emitting units EP1 and EP2 may include sub-light emitting units spaced apart from each other. However, embodiments are not limited thereto.

The light emitting units in the first row Rk may include the light emitting units EP1, EP2, and EP3 forming the first row first column light emitting unit UT11 and the first row second column light emitting unit UT12, and the light emitting units in the second row Rk+1 may include the light emitting units EP1, EP2, and EP3 forming the second row first column light emitting unit UT21 and the second row second column light emitting unit UT22. Some of the light emitting units in the first row Rk and some of the light emitting units in the second row Rk+1 may have symmetrical shapes. For example, the first light emitting unit EP1 and the second light emitting unit EP2 of the second row first column light emitting unit UT21 and the first light emitting unit EP1 and the second light emitting unit EP2 of the first row first column light emitting unit UT11 may have shapes and arrangements that are line-symmetrical to each other with respect to an axis parallel to the first direction DR1. The third light emitting unit EP3 of the second row first column light emitting unit UT21 and the third light emitting unit EP3 of the first row first column light emitting unit UT11 may have shapes and arrangements that are line-symmetrical to each other with respect to an axis parallel to the first direction DR1. However, this is illustrative, and embodiments are not limited thereto.

Hereinafter, the first row first column light emitting unit UT11 will be described. For descriptive convenience, FIG. 4B illustrates the second electrodes EL2_1, EL2_2, and EL2_3 (e.g., EL2_3a and EL2_3b), pixel driving units PDC1, PDC2, and PDC3, and connection wiring lines CN1a, CN1b, CN2a, CN2b, CN3a, and CN3b. The second electrodes EL2_1, EL2_2, and EL2_3 may be separated from each other and electrically disconnected from each other by the separator SPR. In an embodiment, one light emitting unit UT may include the three light emitting units EP1, EP2, and EP3. Accordingly, the light emitting unit UT may include the three second electrodes EL2_1, EL2_2, and EL2_3, the three pixel driving units PDC1, PDC2, and PDC3, and the three connection wiring lines CN1a, CN2a, and CN3a or CN1b, CN2b, and CN3b. However, this is illustratively illustrated, the number and arrangement of the light emitting units UT may be variously designed, and embodiments are not limited thereto.

The first to third pixel driving units PDC1, PDC2, and PDC3 may be connected (e.g., electrically connected) to the light emitting elements forming the first to third light emitting units EP1, EP2, and EP3, respectively. In the description, the wording “connected” includes not only a case of being connected (e.g., physically connected) by direct contact but also a case of being connected (e.g., electrically connected).

Further, as illustrated in FIG. 4B, areas in which the pixel driving units PDC1, PDC2, and PDC3 are defined in plan view may correspond to units in which transistors and capacitor elements forming the circuit PDC (see FIG. 2) for driving the light emitting element of the pixel are repeatedly arranged.

The first to third pixel driving units PDC1, PDC2, and PDC3 may be sequentially arranged in the first direction DR1. For example, the arrangement positions of the first to third pixel driving units PDC1, PDC2, and PDC3 may be independently designed regardless of positions or shapes of the first to third light emitting units EP1, EP2, and EP3.

For example, the first to third pixel driving units PDC1, PDC2, and PDC3 may be areas partitioned and defined by the separator SPR, e.g., may be arranged in positions different from positions in which the second electrodes EL2_1, EL2_2, and EL2_3 are arranged or may be designed to have shapes and areas different from shapes of the second electrodes EL2_1, EL2_2, and EL2_3. In another example, the first to third pixel driving units PDC1, PDC2, and PDC3 may be areas that are arranged to overlap positions in which the first to third light emitting units EP1, EP2, and EP3 are disposed and are partitioned and defined by the separator SPR and, for example, may be designed to have shapes and areas similar to those of the second electrodes EL2_1, EL2_2, and EL2_3.

In an embodiment, the first to third pixel driving units PDC1, PDC2, and PDC3 are illustrated in a rectangular shape, the first to third light emitting units EP1, EP2, and EP3 may be arranged in a smaller area than and a different shape from the first to third pixel driving units PDC1, PDC2, and PDC3, and the second electrodes EL2_1, EL2_2, and EL2_3 may be arranged at positions overlapping the first to third light emitting units EP1, EP2, and EP3 and illustrated in irregular shapes.

Accordingly, as illustrated in FIG. 4B, the first pixel driving unit PDC1 may be disposed at a position partially overlapping the first light emitting unit EP1, the second light emitting unit EP2, and another adjacent light emitting unit(s). The second pixel driving unit PDC2 may be disposed at a position overlapping the first light emitting unit EP1, the second light emitting unit EP2, and the third light emitting unit EP3. The third pixel driving unit PDC3 may be disposed at a position overlapping the third light emitting unit EP3. For example, it is illustratively illustrated, the positions of the first to third pixel driving units PDC1, PDC2, and PDC3 may be designed in various shapes and arrangements independently of the light emitting units EP1, EP2, and EP3, but embodiments are not limited thereto.

A connection wiring line CN may be provided as connection wiring lines CN, which are spaced apart from each other. The single connection wiring line CN may connect (e.g., electrically connect) any single pixel driving unit PDC among the pixel driving units PDC1, PDC2, and PDC3 and the light emitting element corresponding thereto. For example, the connection wiring line CN may correspond to a node in which the light emitting element OLED (see FIG. 2) is connected to the pixel driving unit PDC (see FIG. 2).

The connection wiring line CN may include a first connection part (or a light emitting connection part CE) and a second connection part (or a driving connection part CD). The light emitting connection part CE may be provided on a side of the connection wiring line CN, and the driving connection part CD may be provided on another side of the connection wiring line CN.

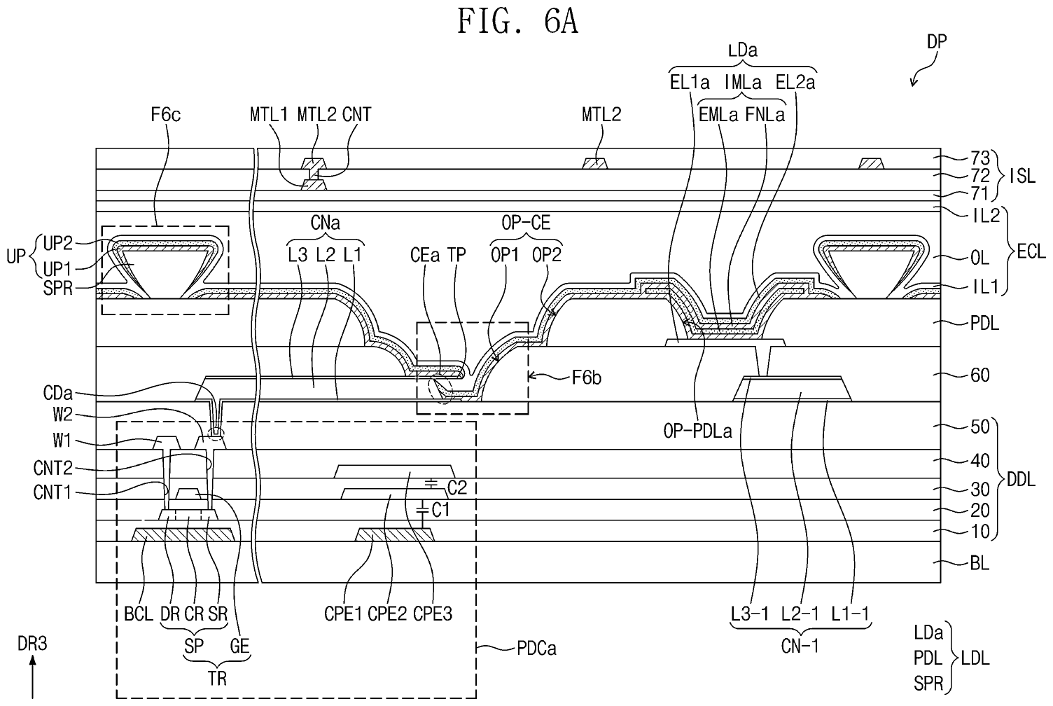

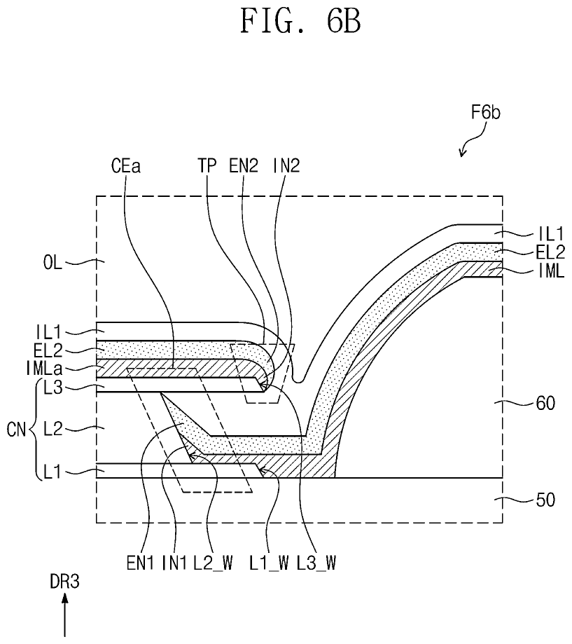

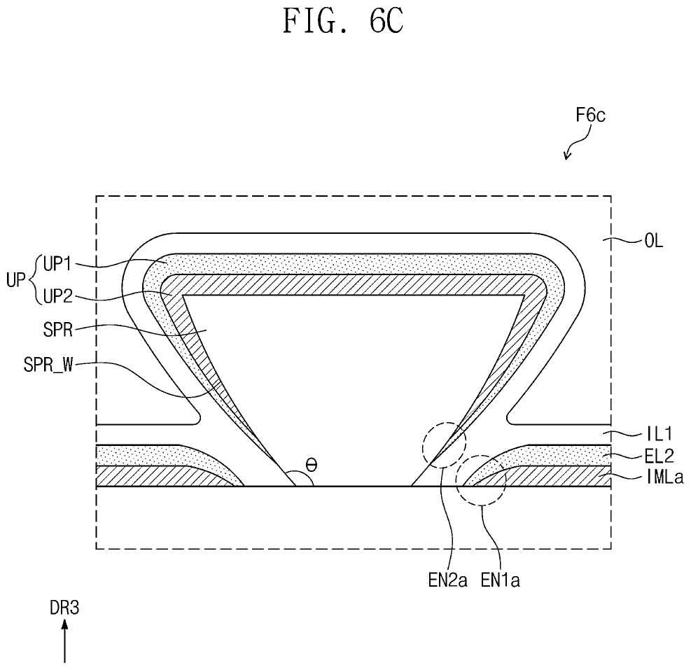

The driving connection part CD may be a part of the connection wiring line CN, which is connected to the pixel driving unit PDC. In an embodiment, the driving connection part CD may be connected to an electrode of the transistor forming the pixel driving unit PDC. Accordingly, the position of the driving connection part CD may correspond to a position of a transistor TR (see FIG. 6A) of the pixel driving unit PDC, which is connected (e.g., physically connected) to the connection wiring line CN. The light emitting connection part CE may be a part of the connection wiring line CN, which is connected to the light emitting element. In an embodiment, the light emitting connection part CE may be connected to a second electrode EL2a (see FIG. 6A) of the light emitting element.

The light emitting unit UT may include the first to third connection wiring lines CN1, CN2, and CN3. The first connection wiring line CN1 may connect the light emitting element forming the first light emitting unit EP1 and the first pixel driving unit PDC1, the second connection wiring line CN2 may connect the light emitting element forming the second light emitting unit EP2 and the second pixel driving unit PDC2, and the third connection wiring line CN3 may connect the light emitting element forming the third light emitting unit EP3 and the third pixel driving unit PDC3.

For example, the first and second connection wiring lines CN1 and CN2 may connect the second electrodes EL2_1 and EL2_2 and the first and second pixel driving units PDC1 and PDC2, respectively (see, e.g., FIG. 6A). The third connection wiring line CN3 may connect the first electrode EL1_3 and the third pixel driving unit PDC3 (see, e.g., FIG. 7). The first connection wiring line CN1 may include a first driving connection part CD1 connected to the first pixel driving unit PDC1 and a first light emitting connection part CE1 connected to a (2-1)^{th} electrode EL2_1. The second connection wiring line CN2 may include a second driving connection part CD2 connected to the second pixel driving unit PDC2 and a second light emitting connection part CE2 connected to a (2-2)^{th} electrode EL2_2. The third connection wiring line CN3 may include a third driving connection part CD3 connected to the third pixel driving unit PDC3 and a third light emitting connection part CE3 connected to a (1-3)th electrode EL1_3.

The first to third driving connection parts CD1, CD2, and CD3 may be aligned in the first direction DR1. As described above, the first to third driving connection parts CD1, CD2, and CD3 may correspond to positions of connection transistors forming the first to third pixel driving units PDC1, PDC2, and PDC3. The connection transistor may be a transistor that includes an electrode, as a connection node, in which the pixel driving unit PDC and the light emitting element are connected to each other in a single pixel. According to an embodiment, regardless of the shape or size of the light emitting unit and the color of the light, the shape, the position, and the arrangement of the pixel driving unit PDC of all the pixels may be simply configured and designed.

In an embodiment, the first to third light emitting connection parts CE1, CE2, and CE3 may be arranged at positions that do not overlap the light emitting units EP1, EP2, and EP3 in plan view. As described above, each of the some light emitting connection parts CE1 and CE2 among the light emitting connection parts CE1, CE2, and CE3 of the connection wiring line CN may be a portion to which a light emitting element LDa (see FIG. 6A) is connected, may be a portion in which a tip portion TP (see FIG. 6A) is defined, and may be provided at a position that does not overlap the light emitting opening OP-PDLa (see FIG. 6A).

The light emitting connection parts CE1, CE2, and CE3 may be arranged at positions spaced apart from the light emitting units EP1, EP2, and EP3 in the second electrodes EL2_1, EL2_2, and EL2_3. Further, some second electrodes EL2_1 and EL2_2 among the second electrodes EL2_1, EL2_2, and EL2_3 may include partial areas protruding from the light emitting units EP1 and EP2 in plan view for connection to the connection wiring lines CN1 and CN2 at positions at which some light emitting connection parts CE1 and CE2 are disposed.

For example, the (2-1)^{th} electrode EL2_1 may include a protrusion part having a shape protruding from the first light emitting unit EP1 at a position that does not overlap the first light emitting unit EP1 for connection to the first connection wiring line CN1 at a position at which the first light emitting connection part CE1 is disposed, and the first light emitting connection part CE1 may be provided (or formed) in the protrusion part of the (2-1)^{th} electrode EL2_1.

Further, the first pixel driving unit PDC1, e.g., the first driving connection part CD1, at a position in which the first connection wiring line CN1 is connected to the transistor TR (see FIG. 6A), may be defined at a position that does not overlap the first light emitting unit EP1 in plan view. According to an embodiment, the first connection wiring line CN1 may be disposed in the first light emitting unit EP1, and thus the (2-1)^{th} electrode EL2_1 and the first pixel driving unit PDC1 spaced apart from each other may be readily connected to each other.

The second power voltage ELVSS (see FIG. 2) may be applied to the (1-1)^{th} electrode EL1_1 and the (1-2)^{th} electrode EL1_2. The first power voltage ELVDD (see FIG. 2) may be applied to the (1-3)^{th} electrode EL1_3.

Referring back to FIG. 4A, the light emitting units in the second row Rk+1 may be light emitting units having a shape and arrangement in which the first row light emitting units UT11 and UT12 are line-symmetrical to each other with respect to an axis parallel to the first direction DR1 or the second direction DR2. For example, due to characteristics of the shape and arrangement of the first row light emitting units UT11 and UT12, the second row light emitting units UT21 and UT22 may be light emitting units in which the first row light emitting units UT11 and UT12 are substantially shifted in the first direction DR1 or the second direction DR2. For example, the second row first column light emitting unit UT21 may be a light emitting unit having the same shape as that of the first row second column light emitting unit UT12, and the second row second column light emitting unit UT22 may be a light emitting unit having the same shape as that of the first row first column light emitting unit UT11.

Accordingly, the shape and arrangement of connection wiring lines CN-c arranged in the second row first column light emitting unit UT21 may be the same as those of connection wiring lines CN1b, CN2b, and CN3b arranged in the first row second column light emitting unit UT12. For example, the shape and arrangement of connection wiring lines CN-d arranged in the second row second column light emitting unit UT22 may be the same as those of the connection wiring lines CN1a, CN2a, and CN3a arranged in the first row first column light emitting unit UT11.

However, embodiments are not limited to the illustration of the accompanying drawings, the third connection wiring line CN3 may be arranged differently, and embodiments are not limited thereto.

Referring to FIG. 4C, the first electrode EL1 of the light emitting element according to an embodiment may be commonly provided (or formed) in the first and second light emitting units EP1 and EP2 and may be independently provided (or formed) in the third light emitting unit EP3. For example, a layer of the first electrode EL1 provided (or formed) in the first and second light emitting units EP1 and EP2 may be disposed to overlap the separator SPR, and a layer of the first electrode EL1 provided (or formed) in the third light emitting unit EP3 may not overlap the separator SPR.

In another example, the first electrodes EL1 of the light emitting elements may be formed as independent conductive patterns spaced apart from each other and may be connected (e.g., electrically connected) to each other through another conductive layer, and accordingly, all patterns of the first electrode EL1 may be arranged so as not to overlap the separator SPR.

The second power voltage ELVSS (see FIG. 2) may be applied to the (1-1)^{th} electrode EL1_1 and the (1-2)^{th} electrode EL1_2. The second power voltage ELVSS (see FIG. 2) may be applied to the (2-3)^{th} electrode EL2_3.

For example, openings may be defined in the (1-1)^{th} electrode EL1_1 and the (1-2)th electrode EL1_2 according to an embodiment, and the openings may pass through layers of the (1-1)^{th} electrode EL1_1 and the (1-2)^{th} electrode EL1_2. The openings formed in the layers of the (1-1)^{th} electrode EL1_1 and the (1-2)^{th} electrode EL1_2 may be arranged at positions that do not overlap the light emitting units EP and may substantially be defined at a position that overlaps the separator SPR. The openings may facilitate (or utilize) discharge of gas generated from an organic layer disposed under the (1-1)^{th} electrode EL1_1 and the (1-2)^{th} electrode EL1_2, for example, a sixth insulating layer 60 (see FIG. 5). Accordingly, in a process of manufacturing the display panel DP, the gas in the organic layer disposed under the light emitting element may be sufficiently discharged, and after the manufacturing, the gas discharged from the organic layer may be reduced, and thus a degradation speed of the light emitting element may be reduced.

According to an embodiment, as the connection wiring line CN is included between the light emitting element and the pixel driving unit PDC, in case that only the shape of the anode or the cathode is changed without changing the arrangement or shape of the light emitting units, the light emitting element may be readily connected to the pixel driving unit PDC. Accordingly, the degree of freedom for the arrangement of the pixel driving unit PDC may be improved, and an area or resolution of the light emitting unit of the display panel DP may readily increase.

FIG. 5 is a schematic cross-sectional view of the display panel DP according to an embodiment.

Referring to FIG. 5, the display panel DP may include a base layer BL, a driving element layer DDL, a light emitting element layer LDL, an encapsulation layer ECL, a sensing layer ISL, and the separator SPR. The driving element layer DDL may include insulating layers 10, 20, 30, 40, and 50 arranged on the base layer BL and conductive patterns and semiconductor patterns arranged between the insulating layers 10, 20, 30, 40, and 50. The conductive patterns and the semiconductor patterns may be arranged between the insulating layers 10, 20, 30, 40, and 50 to form the pixel driving unit PDC. A detailed description of each layer will be made below.

The display panel DP may include a first area AA1, a second area AA2, and a third area AA3. The first area AA1 to the third area AA3 may be divided by the separator SPR. The first area AA1 may overlap a first light emitting element LD1. The first area AA1 may overlap a first light emitting opening OP1-PDL, and at least a portion of the first light emitting element LD1 may be exposed through the first light emitting opening OP1-PDL. The first light emitting element LD1 may include a light emitting material that generates a red light or a green light.

The second area AA2 may overlap a second light emitting element LD2. The second area AA2 may overlap a second light emitting opening OP2-PDL, and at least a portion of the second light emitting element LD2 may be exposed through the second light emitting opening OP2-PDL. The second light emitting element LD2 may include a light emitting material that generates a green light or a red light.

The third area AA3 may overlap a third light emitting element LD3. The third area AA3 may overlap a third light emitting opening OP3-PDL, and at least a portion of the third light emitting element LD3 may be exposed through the third light emitting opening OP3-PDL. The third light emitting element LD3 may include a light emitting material that generates a blue light.

An arrangement relationship between the components of the first light emitting element LD1 disposed in the first area AA1 may be substantially the same as an arrangement relationship between the components of the second light emitting element LD2 disposed in the second area AA2. The arrangement relationship between the components of the first light emitting element LD1 disposed in the first area AA1 may be different from an arrangement relationship between the components of the third light emitting element LD3 disposed in the third area AA3.

For example, referring to an area LD1-A of the first light emitting element LD1 overlapping the first light emitting opening OP1-PDL and an area LD2-A of the second light emitting element LD2 overlapping the second light emitting opening OP2-PDL illustrated in the drawings, as will be described below in FIG. 6A, the (1-1)^{th} electrode EL1_1 (or EL1a) and the (1-2)^{th} electrode EL1_2 (or EL1a) may be cathodes and the (2-1)^{th} electrode EL2_1 (or EL2a) and the (2-2)^{th} electrode EL2_2 (or EL2a) may be anodes. Referring to an area LD3-A of the third light emitting element LD3 overlapping the third light emitting opening OP3-PDL, as will be described below in FIG. 7, a (1-3)^{th} electrode EL1_3 (or EL1b) may be an anode, and a (2-3)^{th} electrode EL2_3 (or EL2b) may be a cathode.

Referring to FIG. 4C together, the (1-1)^{th} electrode EL1 (or a first cathode) of the first light emitting element LD1 and the second electrode EL2a (or a second cathode) of the second light emitting element LD2 may be connected to each other, but the second electrode EL2b (or a third cathode) of the third light emitting element LD3 may be spaced apart from the first cathode of the first light emitting element LD1 and the second cathode of the second light emitting element LD2 in plan view.

Further, embodiments are not limited thereto, and on a cross section parallel to a third direction, a first connection opening OP1-CE in the first area AA1 and a second connection opening OP2-CE in the second area AA2 have similar cross-sectional shapes, but a connection opening may not be disposed in the third area AA3.

For example, the arrangement relationships and the shapes between the components of the first area AA1 and the third area AA3 may be different from each other, and this will be described below.

FIGS. 6A to 6C are enlarged schematic cross-sectional views of the portion of the display panel DP according to an embodiment. FIG. 6A is an enlarged schematic cross-sectional view of a portion of the first area AA1 or a portion of the second area AA2 illustrated in FIG. 5, FIG. 6B is an enlarged schematic cross-sectional view of part F6b illustrated in FIG. 6A, and FIG. 6C is an enlarged schematic cross-sectional view of part F6c illustrated in FIG. 6A.

Referring to FIG. 6A, the base layer BL may be a member providing a base surface on which the pixel driving unit PDC is disposed. The base layer BL may be a rigid substrate or a flexible substrate that is bendable, foldable, and rollable. The base layer BL may be a glass substrate, a metal substrate, a polymer substrate, or the like. However, an embodiment is not limited thereto, and the base layer BL may also be an inorganic layer, an organic layer, or a composite material layer.

The base layer BL may have a multi-layer structure. The base layer BL may include a first polymer resin layer, a silicon oxide (SiOₓ) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin layer may include a polyimide-based resin. Further, the polymer resin layer may include at least one of an acrylate-based resin, a methacrylate-based resin, a polyisoprene-based resin, a vinyl-based resin, an epoxy-based resin, an urethane-based resin, a cellulose-based resin, a siloxane-based resin, a polyamide-based resin, and a perylene-based resin. In the description, a “˜˜ based” resin means a resin containing a functional group of “˜˜”.

The insulating layers, the conductive layers, and the semiconductor layers arranged on the base layer BL may be formed by a coating process and/or a deposition process. Thereafter, by photolithography processes, the insulating layer, the semiconductor layer, and the conductive layer may be selectively patterned so that a hole may be formed in the insulating layer or the semiconductor pattern, the conductive pattern, the signal line, and the like may be formed.

The driving element layer DDL may include the first to fifth insulating layers 10, 20, 30, 40, and 50 and a pixel driving unit PDCa sequentially laminated on the base layer BL. FIG. 5 illustrates a transistor TR and two capacitors C1 and C2 of the pixel driving unit PDCa. The pixel driving unit PDCa may be the first pixel driving unit PDC1 (see FIG. 5) connected (e.g., electrically connected) to the first light emitting element LD1 (see FIG. 5) or the second pixel driving unit PDC2 (see FIG. 5) connected (e.g., electrically connected) to the second light emitting element LD2 (see FIG. 5) illustrated above in FIG. 5.

The transistor TR may correspond to a transistor connected to the light emitting element LDa through a connection wiring line CNa, e.g., a connection transistor connected to a node corresponding to an anode of the light emitting element LDa. For example, the other transistors forming the pixel driving unit PDCa may have the same structure as that of the transistor TR illustrated in FIG. 5. However, this is illustratively described, the other transistors forming the pixel driving unit PDCa may have a structure different from that of the transistor TR illustrated in FIG. 5, and embodiments are not limited thereto.

The first insulating layer 10 may be disposed on the base layer BL. The first insulating layer 10 may be an inorganic layer and/or an organic layer and may have a single-layer structure or a multi-layer structure. The first insulating layer 10 may include at least one of an aluminum oxide, a titanium oxide, a silicon oxide, a silicon nitride, a silicon oxy nitride, a zirconium oxide, or a hafnium oxide. In an embodiment, the first insulating layer 10 is illustrated as a single silicon oxide layer. For example, the insulating layers, which will be described below, may be an inorganic layer and/or an organic layer, and may have a single-layer structure or a multi-layer structure. The inorganic layer may include at least one of the above-described materials, but embodiments are not limited thereto.

For example, the first insulating layer 10 may cover a lower conductive layer BCL. For example, the display panel DP may further include the lower conductive layer BCL disposed to overlap the transistor TR. The lower conductive layer BCL may block an electric potential due to a polarization phenomenon of the base layer BL from affecting the transistor TR. Further, the lower conductive layer BCL may block a light input from a lower side to the transistor TR. At least one of an inorganic barrier layer and a buffer layer may be further disposed between the lower conductive layer BCL and the base layer BL.

The lower conductive layer BCL may include a reflective metal. For example, the lower conductive layer BCL may include titanium (Ti), molybdenum (Mo), an alloy containing molybdenum, aluminum (Al), an alloy containing aluminum, aluminum nitride (AlN), tungsten (W), tungsten nitride (WN), copper (Cu), or the like.

In an embodiment, the lower conductive layer BCL may be connected to a drain of the transistor TR through a drain electrode pattern W1. For example, the lower conductive layer BCL may be synchronized with the drain of the transistor TR. However, this is illustratively illustrated, and the lower conductive layer BCL may be connected to a gate of the transistor TR and synchronized with the gate. In another example, the lower conductive layer BCL may be connected to another electrode to independently receive a constant voltage or pulse signal. In another example, the lower conductive layer BCL may be provided (or formed) in the form of being isolated from other conductive patterns. The lower conductive layer BCL according to an embodiment may be provided (or formed) in various forms and is not limited to an embodiment.

The transistor TR may be disposed on the first insulating layer 10. The transistor TR may include a semiconductor pattern SP and a gate electrode GE. The semiconductor pattern SP may be disposed on the first insulating layer 10. The semiconductor pattern SP may include an oxide semiconductor. For example, the oxide semiconductor may include a transparent conductive oxide TCO such as indium tin oxide (ITO), indium zinc oxide (IZO), indium gallium zinc oxide (IGZO), zinc oxide (ZnO) or indium oxide (In₂O₃). However, embodiments are not limited thereto, and the semiconductor pattern SP may include amorphous silicon, low-temperature polycrystalline silicon, or polycrystalline silicon.

The semiconductor pattern SP may include a source area SR, a drain area DR, and a channel area CR, which are distinguished according to the degree of conductivity. The channel area CR may be a portion overlapping the gate electrode GE in plan view. The source area SR and the drain area DR may be portions spaced apart from each other with the channel area CR interposed therebetween. In case that the semiconductor pattern SP is the oxide semiconductor, the source area SR and the drain area DR may be reduced areas. Accordingly, the source area SR and the drain area DR may have a relatively high reduction metal content compared to the channel area CR. In another example, in case that the semiconductor pattern SP is the polycrystalline silicon, the source area SR and the drain area DR may be areas doped at a high concentration.

The source area SR and the drain area DR may have relatively higher conductivity than that of the channel area CR. The source area SR may correspond to a source electrode of the transistor TR, and the drain area DR may correspond to a drain electrode of the transistor TR. As illustrated in FIG. 5, the separate drain electrode pattern W1 and a separate source electrode pattern W2 respectively connected to the source area SR and the drain area DR may be further provided. For example, the separate drain electrode pattern W1 and the separate source electrode pattern W2 may be integral (or formed integrally) with one of the lines forming the pixel driving unit PDC (see FIG. 2), and embodiments are not limited thereto.

The second insulating layer 20 may commonly overlap the pixels and cover the semiconductor pattern SP. The second insulating layer 20 may be an inorganic layer and/or an organic layer and may have a single-layer structure or a multi-layer structure. The second insulating layer 20 may include at least one of an aluminum oxide, a titanium oxide, a silicon oxide, a silicon nitride, a silicon oxynitride, a zirconium oxide, or a hafnium oxide. In an embodiment, the second insulating layer 20 may be a single-layered silicon oxide layer.

The gate electrode GE may be disposed on the second insulating layer 20. The gate electrode GE may correspond to the gate of the transistor TR. Further, the gate electrode GE may be disposed on the semiconductor pattern SP. However, this is illustratively illustrated, the gate electrode GE may be disposed below the semiconductor pattern SP, and embodiments are not limited thereto.

The gate electrode GE may include titanium (Ti), silver (Ag), molybdenum (Mo), aluminum (Al), aluminum nitride (AlN), tungsten (W), tungsten nitride (WN), copper (Cu), or alloys thereof, but embodiments are not limited thereto.

The third insulating layer 30 may be disposed on the gate electrode GE. The third insulating layer 30 may be an inorganic layer and/or an organic layer and may have a single-layer structure or a multi-layer structure. The fourth insulating layer 40 may include at least one of an aluminum oxide, a titanium oxide, a silicon oxide, a silicon nitride, a silicon oxynitride, a zirconium oxide, or a hafnium oxide.

A first capacitor electrode CPE1 and a second capacitor electrode CPE2 among the conductive patterns W1, W2, CPE1, CPE2, and CPE3 may form the first capacitor C1. The first capacitor electrode CPE1 and the second capacitor electrode CPE2 may be spaced apart from each other with the first insulating layer 10 and the second insulating layer 20 interposed therebetween.

In an embodiment, the first capacitor electrode CPE1 and the lower conductive layer BCL may also have an integral shape. Further, the second capacitor electrode CPE2 and the gate electrode GE may have an integral shape.

The third capacitor electrode CPE3 may be disposed on the third insulating layer 30. The third capacitor electrode CPE3 may be spaced apart from the second capacitor electrode CPE2 with the third insulating layer 30 interposed therebetween and overlap the second capacitor electrode CPE2 in plan view. The third capacitor electrode CPE3 and the second capacitor electrode CPE2 may form the second capacitor C2.

The fourth insulating layer 40 may be disposed on the third insulating layer 30 and/or the third capacitor electrode CPE3. The fourth insulating layer 40 may be an inorganic layer and/or an organic layer and may have a single-layer structure or a multi-layer structure. The fourth insulating layer 40 may include at least one of an aluminum oxide, a titanium oxide, a silicon oxide, a silicon nitride, a silicon oxynitride, a zirconium oxide, or a hafnium oxide.

The drain electrode pattern W1 and the source electrode pattern W2 may be arranged on the fourth insulating layer 40. The drain electrode pattern W1 may be connected to the drain area DR of the transistor TR through a first contact hole CNT1, and the drain electrode pattern W1 and the drain area DR of the semiconductor pattern SP may function as a drain of the transistor TR. The source electrode pattern W2 may be connected to the source area SR of the transistor TR through a second contact hole CNT2, and the source electrode pattern W2 and the source area SR of the semiconductor pattern SP may function as a source of transistor TR. The fifth insulating layer 50 may be disposed on the drain electrode pattern W1 and the source electrode pattern W2.

The connection wiring line CNa may be disposed on the fifth insulating layer 50. The connection wiring line CNa may connect (e.g., electrically connect) the pixel driving unit PDCa and the light emitting element LDa. For example, the connection wiring line CNa may connect (e.g., electrically connect) the transistor TR and the light emitting element LDa. The connection wiring line CNa may be a connection node that connects the pixel driving unit PDCa and the light emitting element LDa. The connection wiring line CNa may be defined as a connection node with various elements among elements forming the pixel driving unit PDCa according to the design of the pixel driving unit PDCa as long as the connection wiring line CNa may be connected to the light emitting element LDa, and embodiments are not limited thereto.

The sixth insulating layer 60 may be disposed on the connection wiring line CNa. The sixth insulating layer 60 may be disposed on the fifth insulating layer 50 to cover the connection wiring line CNa. The fifth insulating layer 50 and the sixth insulating layer 60 may be organic layers. For example, each of the fifth insulating layer 50 and the sixth insulating layer 60 may include polymers such as benzocyclobutene (BCB), polyimide, hexamethyldisiloxane (HMDSO), polymethylmethacrylate (PMMA), and polystyrene (PS), a polymer derivative having a phenolic group, an acryl-based polymer, an imide-based polymer, an arylether-based polymer, an amide-based polymer, a fluorine-based polymer, a p-xylene-based polymer, a vinyl alcohol-based polymer, and blends thereof.

An opening through which at least a portion of the connection wiring line CNa is exposed may be provided (or formed) in the sixth insulating layer 60. The connection wiring line CNa may be connected (e.g., electrically connected) to the light emitting element LDa through the portion thereof exposed from the sixth insulating layer 60. For example, the connection wiring line CNa may connect (e.g., electrically connect) the transistor TR and the light emitting element LDa. A detailed description thereof will be made below. For example, in the display panel DP according to an embodiment, the sixth insulating layer 60 may be omitted or may be provided as sixth insulating layers 60, but embodiments are not limited thereto.

The light emitting element layer LDL may be disposed on the sixth insulating layer 60. The light emitting element layer LDL may include a pixel defining film PDL, the light emitting element LDa, and the separator SPR. The pixel defining film PDL may be an organic layer. For example, the pixel defining film PDL may include polymers such as BCB, polyimide, HMDSO, PMMA, and PS, a polymer derivative having a phenolic group, an acryl-based polymer, an imide-based polymer, an arylether-based polymer, an amide-based polymer, a fluorine-based polymer, a p-xylene-based polymer, a vinyl alcohol-based polymer, and blends thereof.

In an embodiment, the pixel defining film PDL may have a property of absorbing a light and may have, for example, a black color. For example, the pixel defining film PDL may include a black coloring agent. The black coloring agent may include black dye and black pigment. The black coloring agent may include carbon black, metal such as chromium, or an oxide thereof. The pixel defining film PDL may be a light shielding pattern having light shielding characteristics.

An opening OP-PDLa (hereinafter, referred to as a light emitting opening), through which at least a portion of the first electrode EL1a which will be described below is exposed, may be defined in the pixel defining film PDL. The light emitting opening OP-PDLa may be provided as light emitting openings OP-PDLa which are arranged to correspond to the light emitting elements, respectively. All components of the light emitting element LDa may be arranged to overlap the light emitting opening OP-PDLa, and the light emitting opening OP-PDLa may be an area on which a light emitted by the light emitting element LDa is substantially displayed. Accordingly, the shape of the light emitting unit EP (see FIG. 2) may substantially correspond to a shape of the light emitting opening OP-PDLa in plan view.

The light emitting element LDa may include the first electrode EL1a, an intermediate layer IMLa, and the second electrode EL2a. The first electrode EL1a may be a semi-transmissive, transmissive, or reflective electrode. According to an embodiment, the first electrode EL1a may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or compounds thereof and a transparent or translucent electrode layer formed on the reflective layer. The transparent electrode layer or translucent electrode layer may include at least one selected from the group consisting of an indium tin oxide (ITO), an indium zinc oxide (IZO), an indium gallium zinc oxide (IGZO), a zinc oxide (ZnO) or an indium oxide (In₂O₃), and an aluminum doped zinc oxide (AZO). For example, the first electrode EL1a may include a laminated structure of ITO/Ag/ITO.

The light emitting element LDa may be the first light emitting element LD1 (see FIG. 5) or the second light emitting element LD2 (see FIG. 5) described above in FIG. 5.

In an embodiment, the first electrode EL1a may be a cathode of the light emitting element LDa. For example, the second power voltage ELVSS (see FIG. 2) may be applied to the first electrode EL1a. The second electrode EL2a may be an anode of the light emitting element LDa.

On the cross-sectional view of FIG. 5, it is illustrated that the first electrode EL1a overlaps the light emitting opening OP-PDL and does not overlap the separator SPR. However, as illustrated above in FIG. 4C, the first electrodes EL1a of the light emitting elements may have an integral shape and may have a mesh shape or lattice shape in which openings are defined in a partial area thereof. For example, in case that the same second power voltage ELVSS (see FIG. 2) may be applied to the first electrodes EL1a of the light emitting elements LDa, the shape of the first electrode EL1a may be variously provided, and embodiments are not limited thereto.

The first electrode EL1a may be connected to a power connection wiring line CN-1. The second power voltage ELVSS (see FIG. 2) may be applied to the first electrode EL1a through the power connection wiring line CN-1. A first layer L1-1, a second layer L2-1, and a third layer L3-1 of the power connection wiring line CN-1 may have the same physical properties as those of a first layer L1, a second layer L2, and a third layer L3 of the first connection wiring line CN1.

The intermediate layer IMLa may be disposed between the first electrode EL1a and the second electrode EL2a. The intermediate layer IMLa may include a light emitting layer EMLa and a functional layer FNLa. The light emitting element LDa may include the intermediate layer IMLa having various structures, and embodiments are not limited thereto. For example, the functional layer FNLa may be provided as a plurality of layers or as two or more layers spaced apart from each other with the light emitting layer EMLa interposed therebetween. In another example, in an embodiment, the functional layer FNLa may be omitted.

The light emitting layer EMLa may include an organic light emitting material. Further, the light emitting layer EMLa may include an inorganic light emitting material or may be provided as a mixed layer of the organic light emitting material and the inorganic light emitting material. In an embodiment, the light emitting layer EMLa included in each of adjacent light emitting units EP may include light emitting materials displaying different colors. The light emitting layer EMLa illustrated in FIG. 6A may provide either a red light or a green light. However, embodiments are not limited thereto, and all the light emitting layers EMLa arranged in the light emitting units EP may include a light emitting material displaying the same color. For example, the light emitting layer EMLa may provide a blue light or a white light. Further, an embodiment in which the light emitting layer EMLa and the functional layer FNLa have different shapes is illustrated in FIG. 5. However, embodiments are not limited thereto, and the light emitting layer EMLa and the functional layer FNLa may be arranged in the same shape in plan view.

The functional layer FNLa may be disposed between the first electrode EL1a and the second electrode EL2a. For example, the functional layer FNLa may be disposed between the first electrode EL1a and the light emitting layer EMLa or disposed between the second electrode EL2a and the light emitting layer EMLa. In another example, the functional layer FNLa may be disposed both between the first electrode EL1a and the light emitting layer EMLa and between the second electrode EL2a and the light emitting layer EMLa. In an embodiment, it is illustrated that the light emitting layer EMLa is inserted into the functional layer FNLa. However, this is illustratively illustrated, the functional layer FNLa may include a layer disposed between the light emitting layer EMLa and the first electrode EL1a and/or a layer disposed between the light emitting layer EMLa and the second electrode EL2a and may be provided as functional layers FNLa, and embodiments are not limited thereto.

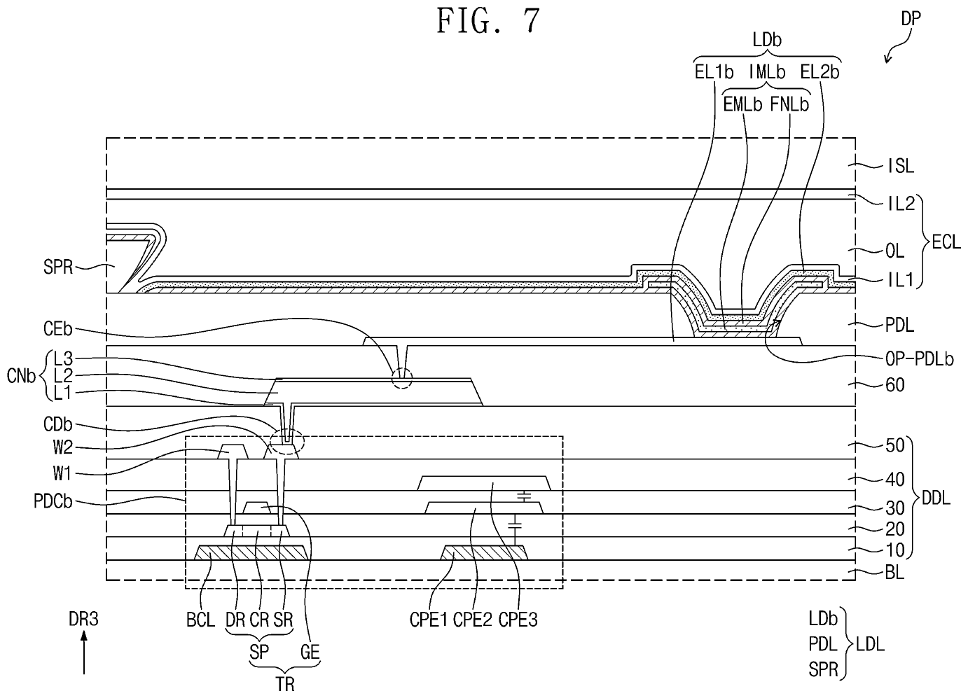

The functional layer FNLa may control movement of charges between the first electrode EL1a and the second electrode EL2a. The functional layer FNLa may include a hole injection/transport material and/or an electron injection/transport material. The functional layer FNLa may include at least one of an electron blocking layer, a hole transporting layer, a hole injecting layer, a hole blocking layer, an electron transporting layer, an electron injecting layer, and a charge generating layer. This will be described below in detail in FIGS. 8A and 8B.

The second electrode EL2a may be disposed on the intermediate layer IMLa. As described above, the second electrode EL2a may be connected to the connection wiring line CNa and connected (e.g., electrically connected) to the pixel driving unit PDCa. For example, the second electrode EL2a may be connected (e.g., electrically connected) to the transistor TR through the connection wiring line CNa.

As described above, the connection wiring line CNa may include a driving connection part CDa and a light emitting connection part CEa. The driving connection part CDa may be a part of the connection wiring line CNa, which is connected to the pixel driving unit PDCa and a part substantially connected to the transistor TR. In an embodiment, the driving connection part CDa may be connected (e.g., electrically connected) to the source area SR of the semiconductor pattern SP through the source electrode pattern W2 with passing through the fifth insulating layer 50. The light emitting connection part CEa may be a part of the connection wiring line CNa, which is connected to the light emitting element LDa. The light emitting connection part CEa may be a part which is defined in an area exposed from the sixth insulating layer 60 and to which the second electrode EL2a is connected. For example, the tip portion TP may be defined in the light emitting connection part CEa.

Referring to FIGS. 6A and 6B, the light emitting connection part CEa of the connection wiring line CNa will be described in more detail. As illustrated in FIGS. 5 and 6A, the connection wiring line CNa may have a three-layered structure. For example, the connection wiring line CNa may include the first layer L1, the second layer L2, and the third layer L3 sequentially laminated in a third direction DR3. The second layer L2 may include a material that is different from that of the first layer L1. Further, the second layer L2 may include a material that is different from that of the third layer L3. The second layer L2 may have a relatively larger thickness than that of the first layer L1. Further, the second layer L2 may have a relatively larger thickness than that of the third layer L3. The second layer L2 may include a material having high conductivity. In an embodiment, the second layer L2 may include aluminum (Al).

For example, the first layer L1 may include a material having a lower etching rate than that of the second layer L2. For example, the second layer L2 may be made of a material having high etching selectivity with respect to the first layer L1. In an embodiment, the first layer L1 may include titanium (Ti), and the second layer L2 may include aluminum (Al). For example, a side surface L1_W of the first layer L1 may be defined outside a side surface L2_W of the second layer L2. For example, the light emitting connection part CEa of the connection wiring line CNa may have a shape in which the side surface L1_W of the first layer L1 protrudes outward from the side surface L2_W of the second layer L2. For example, the light emitting connection part CEa of the connection wiring line CNa may have a shape in which the side surface L2_W of the second layer L2 is recessed inward from the side surface L1_W of the first layer L1.

Further, the third layer L3 may include a material having a lower etching rate than that of the second layer L2. In an embodiment, the third layer L3 may include titanium (Ti), and the second layer L2 may include aluminum (Al). For example, a side surface L3_W of the third layer L3 may be defined outside the side surface L2_W of the second layer L2. For example, the light emitting connection part CEa of the connection wiring line CNa may have a shape in which the side surface L3_W of the third layer L3 protrudes outward from the side surface L2_W of the second layer L2. For example, the light emitting connection part CEa of the connection wiring line CNa may have an undercut shape or an overhang structure, and the tip portion TP of the light emitting connection part CEa may be defined by a portion of the third layer L3, which protrudes from the second layer L2.

The sixth insulating layer 60 and the pixel defining film PDL may expose at least a portion of the tip portion TP and at least a portion of the side surface L2_W. A portion of the connection wiring line CNa may overlap a connection opening OP-CE. For example, a first opening OP1 through which a side of the connection wiring line CNa is exposed may be defined in the sixth insulating layer 60, and a second opening OP2 overlapping the first opening OP1 may be defined in the pixel defining film PDL. A planar area of the second opening OP2 may be greater than a planar area of the first opening OP1. However, embodiments are not limited thereto, and the planar area of the second opening OP2 may be smaller than or equal to the planar area of the first opening OP1 as long as the at least a portion of the tip portion TP and the at least a portion of the side surface L2_W of the second layer L2 may be exposed.

The intermediate layer IMLa may be disposed on the pixel defining film PDL. The intermediate layer IMLa may also be disposed on a partial area of the sixth insulating layer 60, which is exposed by the second opening OP2 of the pixel defining film PDL. Further, the intermediate layer IMLa may also be disposed on a partial area of the connection wiring line CNa, which is exposed by the first opening OP1 of the sixth insulating layer 60. As illustrated in FIG. 6A, the intermediate layer IMLa may include an end portion IN1 disposed along an upper surface of the fifth insulating layer 50 and another end portion IN2 disposed along upper surfaces of the connection wiring line CNa and the tip portion TP. For example, when viewed on a cross section, the intermediate layer IMLa may have a shape that is partially disconnected with respect to the tip portion TP in an area in which the light emitting connection part CEa is defined. However, in plan view, the intermediate layer IMLa may have an integral shape connected as a whole within an area (see FIG. 4) defined as a closed line by the separator SPR.

The second electrode EL2a may be disposed on the intermediate layer IMLa. The second electrode EL2a may also be disposed on a partial area of the sixth insulating layer 60, which is exposed by the second opening OP2 of the pixel defining film PDL. Further, the second electrode EL2a may also be disposed on the partial area of the connection wiring line CNa, which is exposed by the first opening OP1 of the sixth insulating layer 60. As illustrated in FIG. 6A, the second electrode EL2a may include an end portion EN1 disposed along the upper surface of the fifth insulating layer 50 and another end portion EN2 disposed along the upper surfaces of the connection wiring line CNa and the tip portion TP. For example, when viewed on a cross section, the second electrode EL2a may have a shape that is partially disconnected with respect to the tip portion TP in the area in which the light emitting connection part CEa is defined. However, in plan view, the second electrode EL2a may have an integral shape connected as a whole within the area (see FIG. 4) defined as the closed line by the separator SPR.

For example, the end portion EN1 of the second electrode EL2a may be disposed along a side surface of the second layer L2 and may be in contact with the side surface L2_W of the second layer L2. For example, the second electrode EL2a may be formed to be in contact with the side surface L2_W of the second layer L2 exposed from the intermediate layer IMLa by the tip portion TP through a difference between deposition angles of the second electrode EL2a and the intermediate layer IMLa. For example, the second electrode EL2a may be connected to the connection wiring line CNa without a separate patterning process for the intermediate layer IMLa, and accordingly, the light emitting element LDa may be connected (e.g., electrically connected) to the pixel driving unit PDC through the connection wiring line CNa.

Further, in an embodiment, it is illustrated that another end portion IN2 of the intermediate layer IMLa and another end portion EN2 of the second electrode EL2a cover the side surface L3_W of the third layer L3. This is illustratively illustrated, and at least a portion of the side surface L3_W of the third layer L3 may be exposed from another end portion IN2 of the intermediate layer IMLa and/or another end portion EN2 of the second electrode EL2a.

For example, as described above, the display panel DP may include the separator SPR. The separator SPR may be disposed on the pixel defining film PDL. In an embodiment, the second electrode EL2a and the intermediate layer IMLa may be formed by a common depositing process on the pixels through an open mask. For example, the second electrode EL2a and the intermediate layer IMLa may be divided by the separator SPR. As described above, the separator SPR may have a closed line shape for each light emitting unit, and accordingly, the second electrode EL2a and the intermediate layer IMLa may have a divided shape in each light emitting unit. For example, the second electrode EL2a and the intermediate layer IMLa may be electrically independent for each adjacent pixel.

The separator SPR will be described in more detail with reference to FIGS. 6A and 6C. As illustrated in FIG. 6C, the separator SPR may have a reverse tapered shape. For example, an angle θ (hereinafter, referred to as a taper angle) between an upper surface of the pixel defining film PDL and a side surface SPR_W of the separator SPR may be an obtuse angle. However, this is illustratively illustrated, the taper angle θ may be variously set as long as the separator SPR may electrically disconnect the second electrode EL2a in each pixel. Further, the separator SPR may have the same structure as that of the tip portion TP, but embodiments are not limited thereto.

In an embodiment, the separator SPR may include an insulating material, and e.g., may include an organic insulating material. The separator SPR may include an inorganic insulating material, may include a multi-layer structure of the organic insulating material and the inorganic insulating material, and may include a conductive material according to an embodiment. For example, as long as the second electrodes EL2a may be electrically disconnected for each pixel, the type of a material of the separator SPR is not limited. It is illustrated in the drawings that only the second electrodes EL2a of the first light emitting element LD1 (see FIG. 5) and the second light emitting element LD2 (see FIG. 5) may be electrically disconnected in each pixel. However, embodiments are not limited thereto, and the second electrode EL2a of the first light emitting element LD1 (see FIG. 5) and the second electrode EL2b (see FIG. 7) of the third light emitting element LD3 (see FIG. 5) or the second light emitting element LD2 (see FIG. 5) and the second electrode EL2b (see FIG. 7) of the third light emitting element LD3 (see FIG. 5) may be electrically disconnected from each other.

A dummy layer UP may be disposed on the separator SPR. The dummy layer UP may include a first dummy layer UP1 disposed on the separator SPR and a second dummy layer UP2 disposed on the first dummy layer UP1. The first dummy layer UP1 may be formed by the same process as that of the intermediate layer IMLa and include the same material as that of the intermediate layer IMLa. The second dummy layer UP2 may be formed by the same process as that of the second electrode EL2a and include the same material as that of the second electrode EL2a. For example, the first dummy layer UP1 and the second dummy layer UP2 may be formed simultaneously while the intermediate layer IMLa and the second electrode EL2a are formed. In an embodiment, the display panel DP may not include the dummy layer UP.

As illustrated in FIG. 6B, in an embodiment, the second electrode EL2a may include a first end portion EN1a, and the second dummy layer UP2 may include a second end portion EN2a. The first end portion EN1a may be spaced apart from the separator SPR and positioned on the pixel defining film PDL, and the second end portion EN2a may be separated from the first end portion EN1a and positioned on the side surface SPR_W of the separator SPR. However, FIG. 6B illustrates that the first end portion EN1a is spaced apart from the side surface SPR_W of the separator SPR by a predetermined distance, but embodiments are not limited thereto, and the first end portion EN1a may be also in contact with the side surface SPR_W of the separator SPR as long as the first end portion EN1a may be electrically disconnected from the second end portion EN2a. Further, in case that the first end portion EN1a and the second end portion EN2a are connected without being distinguished from each other, in case that electrical resistance is high due to a small thickness of a portion of the separator SPR formed along the side surface SPR_W, and in case that the second electrode EL2a is electrically disconnected between adjacent pixels, it may be considered that the second electrode EL2a is divided by the separator SPR.

According to an embodiment, in case that there is no separate patterning process for the second electrode EL2a or the intermediate layer IMLa, the second electrode EL2a or the intermediate layer IMLa is not formed on the side surface SPR_W of the separator SPR or is formed to be thin, and thus the second electrode EL2a or the intermediate layer IMLa may be divided in each pixel. Further, in case that the second electrode EL2a or the intermediate layer IMLa may be electrically disconnected between the adjacent pixels, the shape of the separator SPR may be variously deformed, but embodiments are not limited thereto.

Referring back to FIG. 6A, the encapsulation layer ECL may be disposed on the light emitting element layer LDL. The encapsulation layer ECL may cover the light emitting element LD and cover the separator SPR. The encapsulation layer ECL may include a first inorganic layer IL1, an organic layer OL, and a second inorganic layer IL2 that are sequentially laminated. However, embodiments are not limited thereto, and the encapsulation layer ECL may further include inorganic layers and organic layers. Further, the encapsulation layer ECL may be a glass substrate.

The first and second inorganic layers IL1 and IL2 may protect the light emitting element LD from moisture and oxygen outside the display panel DP, and the organic layer OL may protect the light emitting element LD from foreign substances such as particles remaining in a process of forming the first inorganic layer IL1. The first and second inorganic layers IL1 and IL2 may include a silicon nitride layer, a silicon oxynitride layer, a silicon oxide layer, a titanium oxide layer, an aluminum oxide layer, or the like. The organic layer OL may include an acryl-based organic layer, and the type of material is not limited thereto.

The sensing layer ISL may sense an external input. In an embodiment, the sensing layer ISL may be formed on the encapsulation layer ECL by a subsequent process. For example, it may be expressed that the sensing layer ISL is directly disposed on the encapsulation layer ECL. The direct disposition may mean that there is no component between the sensing layer ISL and the encapsulation layer ECL. For example, no separate adhesive member may be disposed between the sensing layer ISL and the encapsulation layer ECL. However, this is illustratively illustrated, and in the display panel DP according to an embodiment, the sensing layer ISL may be separately formed and then coupled to the display panel DP through the adhesive member, but embodiments are not limited thereto.

The sensing layer ISL may include conductive layers and insulating layers. The conductive layers may include a first sensing conductive layer MTL1 and a second sensing conductive layer MTL2, and the insulating layers may include first to third sensing insulating layers 71, 72, and 73. However, this is illustratively illustrated, and the numbers of the conductive layers and the insulating layers are not limited to an embodiment.

The first to third sensing insulating layers 71, 72, and 73 may have a single-layer structure or a multi-layer structure in which multiple layers are laminated in the third direction DR3. The first to third sensing insulating layers 71, 72, and 73 may include inorganic films. The inorganic film may include at least one of an aluminum oxide, a titanium oxide, a silicon oxide, a silicon nitride, a silicon oxy nitride, a zirconium oxide, or a hafnium oxide. The first to third sensing insulating layers 71, 72, and 73 may include organic films. The organic film may include at least one of an acryl-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The first sensing conductive layer MTL1 may be disposed between the first sensing insulating layer 71 and the second sensing insulating layer 72, and the second sensing conductive layer MTL2 may be disposed between the second sensing insulating layer 72 and the third sensing insulating layer 73. A portion of the second sensing conductive layer MTL2 may be connected to the first sensing conductive layer MTL1 through a contact hole CNT formed in the second sensing insulating layer 72. The first sensing conductive layer MTL1 and the second sensing conductive layer MTL2 may have a single-layer structure or a multi-layer structure in which multiple layers are laminated in the third direction DR3.

The sensing conductive layer having the single-layer structure may include a metal layer or a transparent conductive layer. The metal layer may include molybdenum, silver, titanium, copper, aluminum, or alloys thereof. The transparent conductive layer may include a transparent conductive oxide such as indium tin oxide (ITO), indium zinc oxide (IZO), zinc oxide (ZnO), or indium zinc tin oxide (IZTO). In another example, the transparent conductive layer may include conductive polymer such as PEDOT, metal nanowire, graphene, or the like.

The sensing conductive layer having the multi-layer structure may include metal layers. For example, the metal layers may have a three-layer structure of titanium (Ti)/aluminum (Al)/titanium (Ti). In another example, the sensing conductive layer having the multi-layer structure may include at least one metal layer and at least one transparent conductive layer. The light emitting element LDb may be disposed in a light emitting opening OP-PDLb.

The first sensing conductive layer MTL1 and the second sensing conductive layer MTL2 may form a sensor that senses an external input in the sensing layer ISL. The sensor may be driven in a capacitive method and may be driven in any one of a mutual capacitive method and a self-capacitive method. However, this is illustratively described, and the sensor may be driven by a resistive film method, an ultrasonic method, or an infrared method in addition to the capacitive method, but embodiments are not limited thereto.

The first sensing conductive layer MTL1 and the second sensing conductive layer MTL2 may include a transparent conductive oxide or may have a shape of a metal mesh formed of an opaque conductive material. The first sensing conductive layer MTL1 and the second sensing conductive layer MTL2 may have various materials and various shapes as long as the visibility of the image displayed by the display panel DP is not degraded, and embodiments are not limited thereto.

FIG. 7 is an enlarged schematic cross-sectional view of the portion of the display panel DP according to an embodiment. FIG. 7 is an enlarged schematic cross-sectional view of the third area AA3 illustrated in FIG. 5.

Referring to FIG. 7, a light emitting element LDb may include a first electrode EL1b, an intermediate layer IMLb, and the second electrode EL2b. In an embodiment, the first electrode EL1b may be an anode of the light emitting element LDb. That is, the first power voltage ELVDD (see FIG. 2) may be applied to the first electrode EL1b. The second electrode EL2b may be a cathode of the light emitting element LDb. The second power voltage ELVSS (see FIG. 2) may be applied to the second electrode EL2b. The light emitting element LDb may be the third light emitting element LD3 (see FIG. 5) described above in FIG. 5. A pixel driving unit PDCb may be the third pixel driving unit PDC3 (see FIG. 5) connected (e.g., electrically connected) to the third light emitting element LD3 (see FIG. 5) described above in FIG. 5.

A connection wiring line CNb may include a driving connection part CDb and a light emitting connection part CEb. The driving connection part CDb may be a part of the connection wiring line CNb, which is connected to the pixel driving unit PDCb and a part substantially connected to the transistor TR. In an embodiment, the driving connection part CDb may be connected (e.g., electrically connected) to the source area SR of the semiconductor pattern SP through the source electrode pattern W2 with passing through the fifth insulating layer 50.

Further, unlike the first area AA1 and the second area AA2, in the third area AA3, the light emitting connection part CEb may not be exposed to the outside. For example, the connection opening OP-CE (see FIG. 6A) may not be defined in part AA3. Further, the connection opening OP-CE (see FIG. 6A) may be spaced apart from part AA3 in plan view.

FIGS. 8A and 8B are enlarged schematic cross-sectional views of the light emitting element according to an embodiment. FIG. 8A is an enlarged schematic cross-sectional view of the light emitting element LDa (see FIG. 6A) illustrated in FIG. 6A, and FIG. 8B is an enlarged schematic cross-sectional view of the light emitting element LDb (see FIG. 7) illustrated in FIG. 7.

As described above, the light emitting element LDa (see FIG. 6) illustrated in FIG. 6A may be the first light emitting element LD1 and the second light emitting element LD2. For convenience of description, the first light emitting element LD1 will be described as an example.

The first light emitting element LD1 may include a first cathode CAT1, a first electron control layer ECL1, a first light emitting layer EML1, a first hole control layer HCL1, and a first anode ANO1.

The first electron control layer ECL1, the first light emitting layer EML1, and the first hole control layer HCL1 of the first light emitting element LD1 may correspond to the intermediate layer IMLa (see FIG. 6A), and the first electron control layer ECL1 and the first hole control layer HCL1 thereof may correspond to the functional layer FNLa (see FIG. 6A).

The first anode ANO1 may be disposed on the first cathode CAT1 of the first light emitting element LD1. The first cathode CAT1 of the first light emitting element LD1 may correspond to the first electrode EL1a (see FIG. 6A), and the first anode ANO1 of the first light emitting element LD1 may correspond to the second electrode EL2a (see FIG. 6A). The first electron control layer ECL1, the first light emitting layer EML1, and the first hole control layer HCL1 may be arranged between the first cathode CAT1 and the first anode ANO1 of the first light emitting element LD1.

The first light emitting layer EML1 may include an organic light emitting material. Further, the first light emitting layer EML1 may include an inorganic light emitting material or may be provided as a mixed layer of the organic light emitting material and the inorganic light emitting material.

In an embodiment, the first light emitting layer EML1 of the first light emitting element LD1 may provide a red light, but embodiments are not limited thereto, and the first light emitting layer EML1 may provide a green light.

The first electron control layer ECL1 and the first hole control layer HCL1 may control movement of charges between the first cathode CAT1 and the first anode ANO1. The first electron control layer ECL1 may include an electron injection/transport material, and the first hole control layer HCL1 may include a hole injection/transport material.

The first hole control layer HCL1 may include a first hole transport layer HCL1-1 and a first hole injection layer HCL1-2. The first hole injection layer HCL1-2 may be disposed on the first hole transport layer HCL1-1. The first hole transport layer HCL1-1 may include ZnO, ZnMgO, an inorganic material or the like, but embodiments are not limited thereto, and the first hole transport layer HCL1-1 may include various materials.

The second light emitting element LD2 may include a second cathode CAT2, a second electron control layer ECL2, a second light emitting layer EML2, a second hole control layer HCL2, and a second anode ANO2.

The second electron control layer ECL2, the second light emitting layer EML2, and the second hole control layer HCL2 may correspond to the intermediate layer IMLa (see FIG. 6A), and the second electron control layer ECL2 and the second hole control layer HCL2 may correspond to the functional layer FNLa (see FIG. 6A).

The second cathode CAT2 may correspond to the first electrode EL1a (see FIG. 6A), and the second anode ANO2 may correspond to the second electrode EL2a (see FIG. 6A). The second electron control layer ECL2, the second light emitting layer EML2, and the second hole control layer HCL2 may be arranged between the second cathode CAT2 and the second anode ANO2.

The second light emitting layer EML2 of the second light emitting element LD2 may provide a green light, but embodiments are not limited thereto, and the second light emitting layer EML2 may provide a red light.

The second electron control layer ECL2 may include an electron injection/transport material, and the second hole control layer HCL2 may include a hole injection/transport material.

The first hole control layer HCL1 and the second hole control layer HCL2 may be arranged on the first light emitting layer EML1 and the second light emitting layer EML2. Thus, in an operation of forming a third light emitting layer EML3 (see FIG. 8B), which will be described below, the first light emitting layer EML1 and the second light emitting layer EML2 may be prevented from being damaged due to a solvent used to form the third light emitting layer EML3 (see FIG. 8B).

A thickness of the first electron control layer ECL1 and the second electron control layer ECL2 may be smaller than a thickness of the first hole control layer HCL1 and the second hole control layer HCL2. As an example, the thickness of the first electron control layer ECL1 and the second electron control layer ECL2 may be about 200 Å or more and about 400 Å or less.

Referring to FIG. 8B, the third light emitting element LD3 may include a third anode ANO3, a third hole control layer HCL3, the third light emitting layer EML3, a third electron control layer ECL3, and a third cathode CAT3.

The third hole control layer HCL3, the third light emitting layer EML3, and the third electron control layer ECL3 of the third light emitting element LD3 may correspond to the intermediate layer IMLb (see FIG. 7), and the third hole control layer HCL3 and the third electron control layer ECL3 thereof may correspond to a functional layer FNLb (see FIG. 7). A light emitting layer EMLb (see FIG. 7) may be disposed between the first electrode EL1b and the functional layer FNLb.

The third anode ANO3 of the third light emitting element LD3 may correspond to the first electrode EL1b (see FIG. 7), and the third cathode CAT3 may correspond to the second electrode EL2b (see FIG. 7). The third hole control layer HCL3, the third light emitting layer EML3, and the third electron control layer ECL3 may be arranged between the third anode ANO3 and the third cathode CAT3.

The third light emitting layer EML3 may include an organic light emitting material. Further, the third light emitting layer EML3 may include an inorganic light emitting material or may be provided as a mixed layer of the organic light emitting material and the inorganic light emitting material.

In an embodiment, the third light emitting layer EML3 of the third light emitting element LD3 may provide a blue light.

The third hole control layer HCL3 and the third electron control layer ECL3 may control movement of charges between the third anode ANO3 and the third cathode CAT3. The third hole control layer HCL3 may include a hole injection/transport material, and the third electron control layer ECL3 may include an electron injection/transport material.

The third hole control layer HCL3 may include a third hole transport layer HCL3-1 and a third hole injection layer HCL3-2. The third hole injection layer HCL3-2 may be disposed on the third hole transport layer HCL3-1.

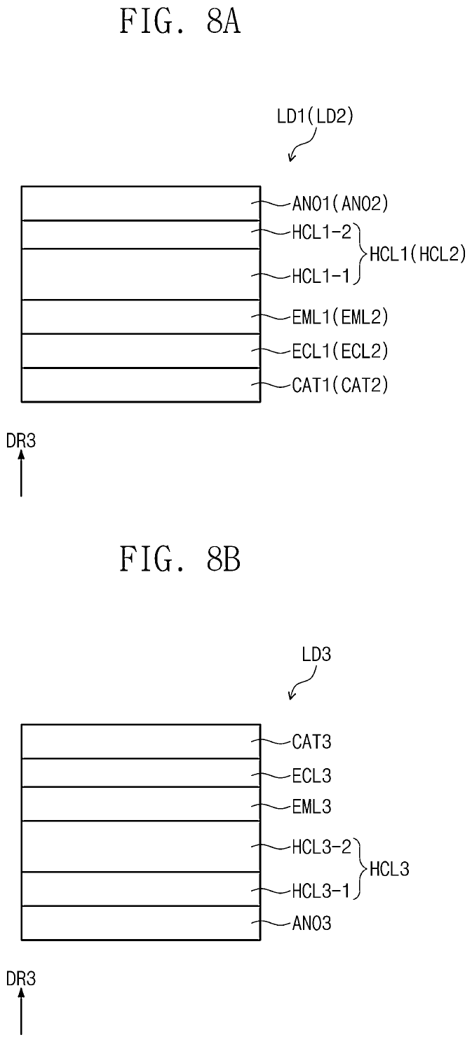

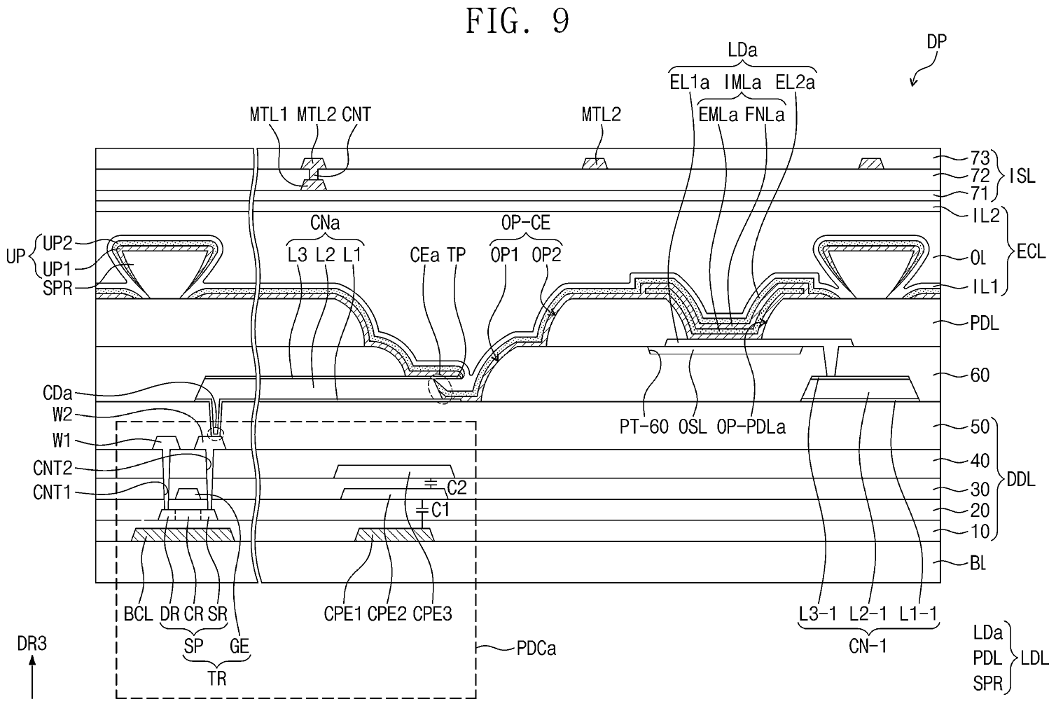

FIG. 9 is an enlarged schematic cross-sectional view of the portion of the display panel DP according to an embodiment. FIG. 9 illustrates an embodiment and another embodiment of part AA1 illustrated in FIG. 6A.

In describing FIG. 9, the same/similar reference numerals are assigned to the same/similar components illustrated in FIG. 6A, and detailed descriptions thereof will be omitted for descriptive convenience.

Referring to FIG. 9, the display panel DP may include a hydrogen supply film OSL. The hydrogen supply film OSL may be disposed between the light emitting element LDa and the sixth insulating layer 60. The hydrogen supply film OSL may increase electrical conductivity of the first electrode EL1a of the light emitting element LDa. For example, the hydrogen supply film OSL may inject/transport charges to the first electrode EL1a provided as the cathode so as to increase the electrical conductivity of the first electrode EL1a. Therefore, efficiency and a lifespan of the light emitting element LDa may be improved.

According to an embodiment, the hydrogen supply film OSL may include silicon nitride (SiNₓ) or poly acrylic acid. However, embodiments are not limited thereto, and the hydrogen supply film OSL may include other materials.

As illustrated in the drawings, a recessed pattern PT-60 may be formed in the sixth insulating layer 60, and the hydrogen supply film OSL may be disposed on the recessed pattern PT-60. However, embodiments are not limited thereto, the hydrogen supply film OSL may be disposed on the sixth insulating layer 60 without a separate recessed pattern PT-60, and embodiments are not limited thereto.

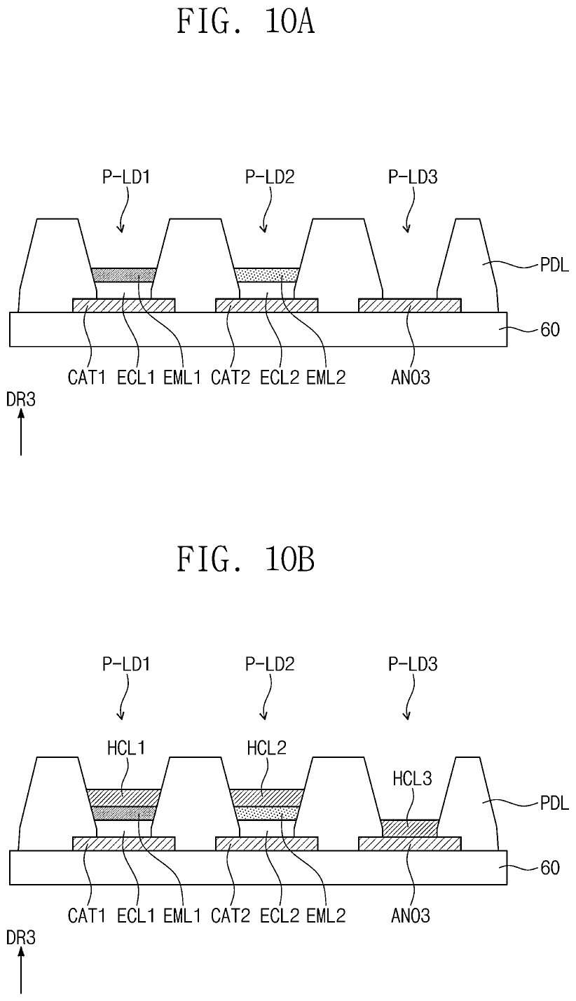

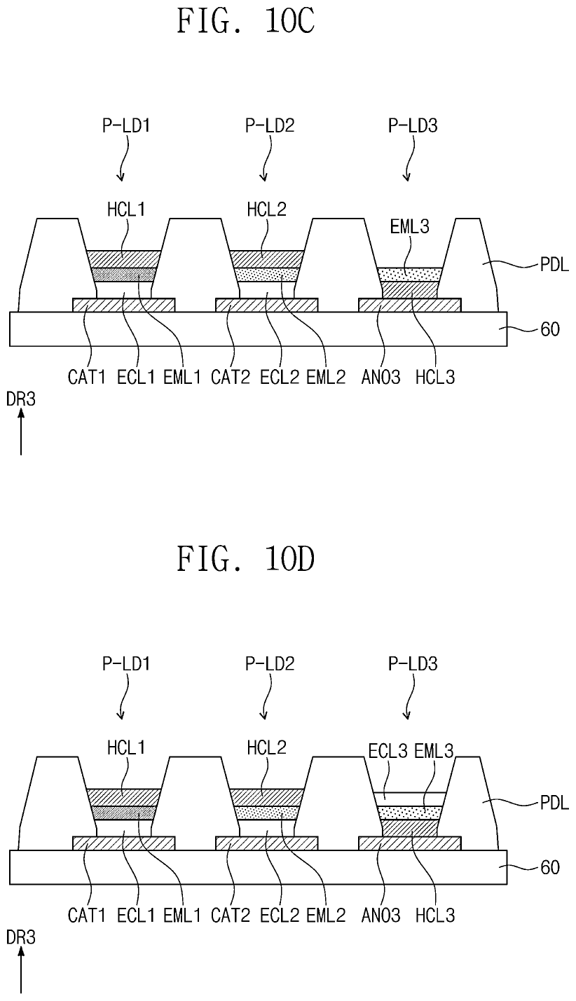

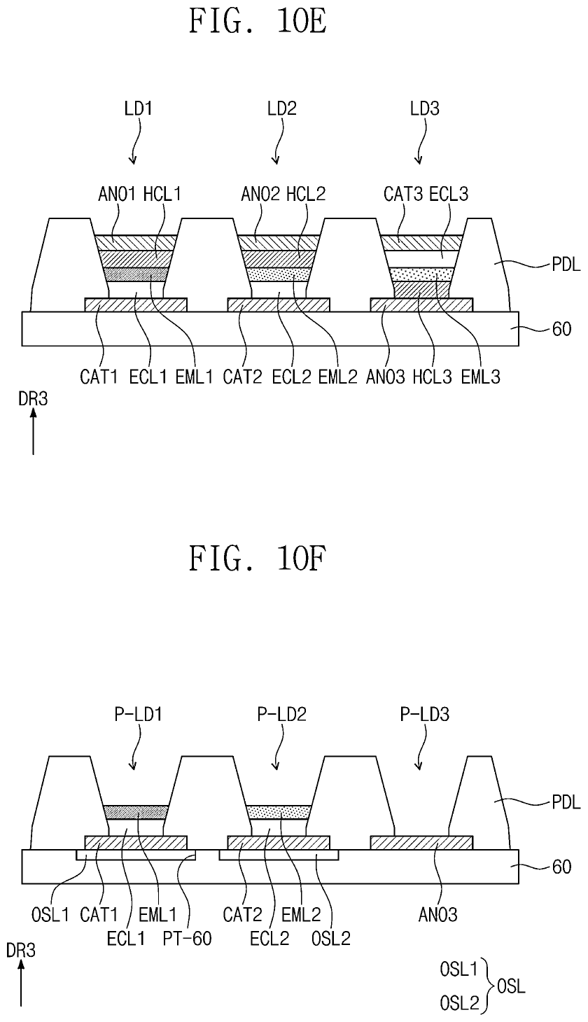

FIGS. 10A, 10B, 10C, 10D, 10E, and 10F are schematic cross-sectional views illustrating a method of manufacturing the display panel DP according to an embodiment.

A method of manufacturing a display panel DP according to an embodiment may include an operation of forming the first lower electrode CAT1, the second lower electrode CAT2, and the third lower electrode ANO3 on the base layer BL (see FIG. 5), an operation of forming the pixel defining film PDL which is disposed on the base layer BL (see FIG. 5) and covers the first lower electrode CAT1, the second lower electrode CAT2, and the third lower electrode ANO3 and in which the first light emitting opening OP1-PDL (see FIG. 5) through which at least a portion of the first lower electrode CAT1 is exposed, the second light emitting opening OP2-PDL (see FIG. 5) through which at least a portion of the second lower electrode CAT2 is exposed, and the third light emitting opening OP3-PDL (see FIG. 5) through which at least a portion of the third lower electrode ANO3 are exposed, an operation of forming the first electron control layer ECL1, the first light emitting layer EML1, and the first hole control layer HCL1 inside the first light emitting opening OP1-PDL (see FIG. 5), an operation of forming the second electron control layer ECL2, the second light emitting layer EML2, and the second hole control layer HCL2 inside the second light emitting opening OP2-PDL (see FIG. 5), and an operation of forming the third hole control layer HCL3, the third light emitting layer EML3, and the third electron control layer ECL3 inside the third light emitting opening OP3-PDL (see FIG. 5).

Further, the first hole control layer HCL1, the second hole control layer HCL2, and the third hole control layer HCL3 may be formed simultaneously.

Referring to FIG. 10A, the pixel defining film PDL may be disposed on the sixth insulating layer 60. The lower electrodes CAT1, CAT2, and ANO3 may be formed in the first light emitting opening OP1-PDL (see FIG. 5), the second light emitting opening OP2-PDL (see FIG. 5), and the third light emitting opening OP3-PDL (see FIG. 5) formed in the pixel defining film PDL.

The first lower electrode CAT1 may be formed in the first light emitting opening OP1-PDL (see FIG. 5), the second lower electrode CAT2 may be formed in the second light emitting opening OP2-PDL (see FIG. 5), and the third lower electrode ANO3 may be formed in the third light emitting opening OP3-PDL (see FIG. 5).

The first lower electrode CAT1 of a first preliminary light emitting element P-LD1 formed in the first light emitting opening OP1-PDL (see FIG. 5) may correspond to the first cathode CAT1 (see FIG. 8A) of the first light emitting element LD1 (see FIG. 8A). The second lower electrode CAT2 of a second preliminary light emitting element P-LD2 formed in the second light emitting opening OP2-PDL (see FIG. 5) may correspond to the second cathode CAT2 of the second light emitting element LD2 (see FIG. 8A). The third lower electrode ANO3 of a third preliminary light emitting element P-LD3 formed in the third light emitting opening OP3-PDL (see FIG. 5) may correspond to the third anode ANO3 of the third light emitting element LD3 (see FIG. 8A).

The first electron control layer ECL1 may be disposed on the first lower electrode CAT1 of the first preliminary light emitting element P-LD1 formed in the first light emitting opening OP1-PDL (see FIG. 5). The first light emitting layer EML1 may be disposed on the first electron control layer ECL1.

The second electron control layer ECL2 may be disposed on the second lower electrode CAT2 of the second preliminary light emitting element P-LD2 formed in the second light emitting opening OP2-PDL (see FIG. 5). The second light emitting layer EML2 may be disposed on the second electron control layer ECL2.

Referring to FIG. 10B, the first hole control layer HCL1 may be formed on the first light emitting layer EML1, the second hole control layer HCL2 may be formed on the second light emitting layer EML2, the third electron control layer ECL3 may be formed on the third light emitting layer EML3.

For example, the first hole control layer HCL1, the second hole control layer HCL2, and the third hole control layer HCL3 may be formed simultaneously.

In case that the first hole control layer HCL1, the second hole control layer HCL2, and the third hole control layer HCL3 are formed and then, in case that the third light emitting layer EML3 is formed, the first hole control layer HCL1 may cover the first light emitting layer EML1 and the second hole control layer HCL2 may cover the second light emitting layer EML2 so that the first light emitting layer EML1 and the second light emitting layer EML2 may be prevented from being damaged. Therefore, a decrease in efficiency of the first light emitting layer EML1 and the second light emitting layer EML2 may be prevented, and lifespans thereof may increase.

Referring to FIG. 10C, the third light emitting layer EML3 may be formed on the third hole control layer HCL3.

As described above, in case that the third light emitting layer EML3 is formed, the first light emitting layer EML1 and the second light emitting layer EML2 may be prevented from being damaged by the first hole control layer HCL1 and the second hole control layer HCL2.

Referring to FIGS. 10D and 10E, the third electron control layer ECL3 may be formed on the third light emitting layer EML3, the first upper electrode ANO1 may be formed on the first hole control layer HCL1, the second upper electrode ANO2 may be formed on the second hole control layer HCL2, and the third upper electrode CAT3 may be formed on the third electron control layer ECL3.

Referring to FIG. 10F, the hydrogen supply film OSL may be formed on the sixth insulating layer 60 before the first lower electrode CAT1 and the second lower electrode CAT2 are formed. The first lower electrode CAT1 and the second lower electrode CAT2 may be formed on a first hydrogen supply film OSL1 and a second hydrogen supply film OSL2, respectively.

It is illustrated in the drawing that the recessed pattern PT-60 is formed in the sixth insulating layer 60 and the hydrogen supply film OSL is disposed in the recessed pattern PT-60, but embodiments are not limited thereto, and the hydrogen supply film OSL may be disposed on the sixth insulating layer 60 without a separate recessed pattern PT-60.

A display panel DP and a method of manufacturing the display panel DP according to an embodiment may prevent damage to a light emitting layer EMLa.

A display panel DP and a method of manufacturing the display panel DP according to an embodiment may prevent reliability of display quality from being degraded.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display panel comprising:
a first light emitting element including a first anode, a first cathode disposed on the first anode, and a first intermediate layer disposed between the first anode and the first cathode;
a second light emitting element including a second cathode, a second anode disposed on the second cathode, and a second intermediate layer disposed between the second cathode and the second anode;
a first transistor electrically connected to the first light emitting element;
a second transistor electrically connected to the second light emitting element;
a connection wiring line disposed between the second light emitting element and the second transistor on a cross section and including a driving connection part connected to the second transistor and a light emitting connection part connected to the second anode; and
a pixel defining film including:
a first light emitting opening overlapping the first light emitting element and in which a portion of the first cathode is disposed,
a second light emitting opening overlapping the second light emitting element and spaced apart from the first light emitting opening, the second light emitting opening in which a portion of the second anode is disposed, and
a first connection opening spaced apart from the first light emitting opening and the second light emitting opening,
wherein the second anode includes an end portion connected to the light emitting connection part and another end portion spaced apart from the end portion on a cross section.

2. The display panel of claim 1, further comprising:
a hydrogen supply film disposed under the second cathode and overlapping the second light emitting opening.

3. The display panel of claim 1, further comprising:
a separator disposed on the pixel defining film and disconnecting the second anode.

4. The display panel of claim 1, wherein
the first intermediate layer includes a light emitting material that generates a light having a blue color, and
the second intermediate layer includes a light emitting material that generates a light having a color different from the blue color.

5. The display panel of claim 1, wherein
the first intermediate layer includes:
a first hole control layer disposed on the pixel defining film;
a first light emitting layer disposed on the first hole control layer, the first light emitting layer that generates a light having a first color; and
a first electron control layer disposed on the first light emitting layer, and the second intermediate layer includes:
a second electron control layer disposed on the pixel defining film;
a second light emitting layer disposed on the second electron control layer and including a light emitting material that generates a light having a color different form the first color; and
a second hole control layer disposed on the second light emitting layer.

6. The display panel of claim 2, wherein the hydrogen supply film contains silicon nitride (SiNₓ) or poly acrylic acid.

7. The display panel of claim 5, wherein a thickness of the second electron control layer is about 200 Å or more and about 400 Å or less.

8. The display panel of claim 1, wherein the connection wiring line includes:
a first layer containing titanium (Ti);
a second layer disposed on the first layer and containing aluminum (Al); and
a third layer disposed on the second layer and containing titanium (Ti).

9. The display panel of claim 1, wherein the first cathode and the second cathode are spaced apart from each other in plan view.

10. The display panel of claim 3, wherein
the first light emitting element is disposed in a first area,
the second light emitting element is disposed in a second area,
the first area and the second area are divided by the separator, and
the first connection opening is spaced apart from the first area in plan view.

11. A display panel comprising:
a first light emitting element including:
a first anode,
a first cathode disposed on the first anode, and
a first intermediate layer disposed between the first anode and the first cathode;
a second light emitting element including:
a second cathode,
a second anode disposed on the second cathode, and
a second intermediate layer disposed between the second cathode and the second anode;
a third light emitting element including:
a third cathode,
a third anode disposed on the third cathode, and
a third intermediate layer disposed between the third cathode and the third anode;
a first transistor electrically connected to the first light emitting element;
a second transistor electrically connected to the second light emitting element;
a third transistor electrically connected to the third light emitting element;
a first connection wiring line disposed between the second light emitting element and the second transistor on a cross section, the first connection wiring line including:
a first driving connection part connected to the second transistor, and
a first light emitting connection part connected to the second anode; and
a second connection wiring line disposed between the third light emitting element and the third transistor on a cross section, the second connection wiring line including:
a second driving connection part connected to the third transistor, and
a second light emitting connection part connected to the third anode, wherein
the second anode includes an end portion connected to the first light emitting connection part and another end portion spaced apart from the end portion on a cross section, and
the third anode includes an end portion connected to the second light emitting connection part and another end portion spaced apart from the end portion on a cross section.

12. The display panel of claim 11, wherein
the first intermediate layer includes a light emitting material that generates a light having a blue color,
the second intermediate layer includes a light emitting material that generates a light having a red color, and
the third intermediate layer includes a light emitting material that generates a light having a green color.

13. The display panel of claim 11, further comprising:
a first hydrogen supply film disposed under the second cathode; and
a second hydrogen supply film disposed under the third cathode.

14. The display panel of claim 11, further comprising:
a separator disconnecting the second anode and the third anode.

15. The display panel of claim 11, wherein the second cathode and the third cathode are electrically connected to each other.

16. The display panel of claim 11, wherein each of the first connection wiring line and the second connection wiring line includes:
a first layer containing titanium (Ti);
a second layer disposed on the first layer and containing aluminum (Al); and
a third layer disposed on the second layer and containing titanium (Ti).

17. The display panel of claim 14, wherein
the first light emitting element is disposed in a first area,
the second light emitting element is disposed in a second area, the third light emitting element is disposed in a third area,
the first area, the second area, and the third area are divided by the separator, and
the first light emitting connection part and the second light emitting connection part are spaced apart from the first area in plan view.

18. A method of manufacturing a display panel, the method comprising:
forming a first lower electrode and a second lower electrode on a base layer;
forming a first light emitting opening through which at least a portion of the first lower electrode is exposed and a second light emitting opening through which at least a portion of the second lower electrode is exposed, the first light emitting opening and the second light emitting opening being arranged on the base layer and covering the first lower electrode and the second lower electrode;
forming a first hole control layer, a first light emitting layer, and a first electron control layer inside the first light emitting opening; and
forming a second electron control layer, a second light emitting layer, and a second hole control layer inside the second light emitting opening,
wherein the first hole control layer and the second hole control layer are formed simultaneously.

19. The method of claim 18, wherein the first and second hole control layers, the first and second light emitting layers, and the first and second electron control layers are formed by an inkjet manner.

20. The method of claim 18, further comprising:
pattering the base layer and forming a hydrogen supply film on the patterned base layer before the first lower electrode and the second lower electrode are formed on the base layer,
wherein the second lower electrode is formed on the hydrogen supply film.
